(19) United States
(12) Patent Application Publication
(10) Pub. No.: US 2026/0222702 A1
(43) Pub. Date: Jul. 30, 2026

(54) PHOTODETECTION DEVICE AND ELECTRONIC APPARATUS

(71) Applicant: SONY SEMICONDUCTOR SOLUTIONS CORPORATION, KANAGAWA (JP)

(72) Inventors: INDIKA BOGODA, KANAGAWA (JP); TOSHIO TERANO, KANAGAWA (JP); TAKUYA KUDO, KANAGAWA (JP)

(21) Appl. No.: 19/146,728

(22) PCT Filed: Jan. 9, 2024
(86) PCT No.: PCT/JP2024/000210

§ 371 Date: Jul. 9, 2025

(30) Foreign Application Priority Data
Jan. 17, 2023 (JP) 2023-005483

(51) Int. Cl. H04N 25/707; H04N 25/62

(52) U.S. Cl. CPC H04N 25/707; H04N 25/62

(57) ABSTRACT

Luminance information is obtained using pixels that detect luminance changes. A photodetection device includes a plurality of pixels that detects events based on an amount of change in illuminance of incident light and that detects noise events whose rate of occurrence changes in accordance with the illuminance of the incident light, and a luminance information generation unit that generates luminance information for each of the plurality of pixels on the basis of the number of noise events that have occurred in the pixel.

### TECHNICAL FIELD

The present disclosure relates to a photodetection device and an electronic apparatus.

### BACKGROUND ART

An event-based vision sensor (EVS) has been proposed that detects some event such as a luminance change in an imaging scene. The EVS has a feature that an event can be detected at higher speed with smaller power than a frame-based vision sensor that scans all pixels at predetermined time intervals to obtain grayscale information regarding each of pixels, or more specifically, a complementary metal oxide semiconductor (CMOS) image sensor (hereinafter CIS), or the like. From such a characteristic, use of the EVS in various scenes has been proposed. For example, Patent Document 1 proposes a technique for obtaining positional information regarding a user, posture information regarding a camera, and the like using the EVS and generating a display image indicating a state of the user.

### CITATION LIST

### Patent Document

Patent Document 1: Japanese Patent Application Laid-Open No. 2022-162703

### SUMMARY OF THE INVENTION

### Problems to be Solved by the Invention

The EVS has a problem that an object with no luminance change cannot be detected due to the characteristic of detecting a luminance change. Specifically, the EVS cannot generate a grayscale image indicating luminance of a stationary object. For example, in a case of calibrating a camera or in a case of tracking an object that is stationary or slow in movement, both event information by the EVS and grayscale information by the CIS are required, and problems such as an increase in size of a sensor and an increase in power consumption occur.

The present disclosure has been made in view of such circumstances, and provides a photodetection device and an electronic apparatus capable of obtaining luminance information using pixels that detect a luminance change.

### Solutions to Problems

In order to solve the above problem, the present disclosure provides a photodetection device including:
a plurality of pixels that detects events based on an amount of change in illuminance of incident light and that detects noise events whose rate of occurrence changes in accordance with the illuminance of the incident light; and
a luminance information generation unit that generates luminance information for each of the plurality of pixels on the basis of the number of noise events that have occurred in the pixel.

Each of the plurality of pixels may have at least one illuminance range in which the rate of occurrence of noise events monotonously increases or decreases in accordance with the illuminance, and
the luminance information generation unit may generate the luminance information in the illuminance range.

The luminance information generation unit may generate the luminance information under a situation where the illuminance of the incident light incident on the plurality of pixels does not change.

The photodetection device may further include:
an accumulation unit that accumulates information regarding the noise events for each of the plurality of pixels, in which
the luminance information generation unit generates the luminance information on the basis of the information regarding the noise events accumulated in the accumulation unit for each of the plurality of pixels.

The luminance information generation unit may generate the luminance information in a case where the information regarding the noise events accumulated in the accumulation unit satisfies a predetermined accumulation condition.

The accumulation unit may count a number of noise events that have occurred in each of the plurality of pixels,
the accumulation unit may accumulate the information regarding the noise events until a total value of the number of noise events that have occurred and been counted for each of the plurality of pixels reaches a predetermined value, and
in a case where the total value reaches the predetermined value, the luminance information generation unit may determine that the accumulation condition is satisfied and generate the luminance information.

The accumulation unit may accumulate the information regarding the noise events until either a maximum value of the number of noise events that have occurred in each of the plurality of pixels or an average value of the number of noise events that have occurred in each of the plurality of pixels reaches a predetermined value, and
in a case where the maximum value or the average value reaches the predetermined value, the luminance information generation unit may determine that the accumulation condition is satisfied and generate the luminance information.

The photodetection device may further include:
a photodetection element that includes the plurality of pixels and that outputs first event frames including information regarding a plurality of the noise events detected asynchronously by the plurality of pixels, in which
the accumulation unit may accumulate information regarding the noise events included in the first event frames until a total number of first event frames reaches a predetermined value, and
in a case where the total number reaches the predetermined value, the luminance information generation unit may determine that the accumulation condition is satisfied and generate the luminance information.

Each of the plurality of pixels asynchronously may detect the noise events,
the accumulation unit may count the number of noise events that have occurred until a predetermined time has elapsed, and
in a case where the predetermined time has elapsed, the luminance information generation unit may determine that the accumulation condition is satisfied and generate the luminance information.

The photodetection device may further include:
an event frame generation section that generates second event frames including the information regarding the noise events detected by the plurality of pixels, in which
the accumulation unit may count the number of noise events that have occurred until a total number of second event frames reaches a predetermined value, and
in a case where the total number reaches the predetermined value, the luminance information generation unit may determine that the accumulation condition is satisfied and generate the luminance information.

The photodetection device may further include:
a luminance image generation unit that generates luminance image data on the basis of the luminance information regarding each of the plurality of pixels, in which
the luminance image data may have a luminance value according to the illuminance for each of the plurality of pixels.

The luminance image generation unit may limit, among luminance values of the pixels included in the luminance image data, a luminance value exceeding a predetermined threshold to a predetermined luminance value.

The luminance image generation unit may limit, among luminance values of the pixels included in the luminance image data, a luminance value below a predetermined threshold to a predetermined luminance value.

The photodetection device may further include:
a plurality of first pixels that detects events based on an amount of change in illuminance of incident light and noise events whose rate of occurrence changes in accordance with the illuminance;
a plurality of second pixels that outputs pixel signals based on the illuminance of the incident light; and
a grayscale image generation unit that generates grayscale image data on the basis of the pixel signals output from the plurality of second pixels, in which
the luminance information generation unit may generate the luminance information for each of the plurality of first pixels, and
the luminance image data may have a luminance value according to the luminance for each of the plurality of first pixels.

The photodetection device may further include:
an analog-to-digital conversion unit that converts the pixel signals into digital signals, in which
the grayscale image generation unit may generate the grayscale image data on the basis of the digital signal corresponding to each of the plurality of pixels.

The luminance image data may have a resolution lower than a resolution of the grayscale image data, and
the luminance image data may include monochrome information, whereas the grayscale image data may include at least one of monochrome information or color information.

The photodetection device may further include an image selection unit that exclusively outputs the luminance image data or the grayscale image data.

The image selection unit may select the luminance image data until an imaging timing of the plurality of second pixels, and select the grayscale image data at the imaging timing.

In addition, the present disclosure provides an electronic apparatus including:
a photodetection device that generates luminance information; and
an information processing unit that performs predetermined information processing on the basis of the luminance information, in which
the photodetection device may include:
   a plurality of pixels that detects events based on an amount of change in illuminance of incident light and that detects noise events whose rate of occurrence changes in accordance with the illuminance of the incident light; and
   a luminance information generation unit that generates the luminance information for each of the plurality of pixels on the basis of the number of noise events that have occurred in the pixel.

### BRIEF DESCRIPTION OF DRAWINGS

FIG. 1 is a block diagram of an electronic apparatus according to a first embodiment of the present disclosure.

FIG. 2 is a block diagram of a photodetection device according to the first embodiment of the present disclosure.

FIG. 3A is a block diagram illustrating an internal configuration of an arbiter-based sensor.

FIG. 3B is a block diagram illustrating an internal configuration of a frame-based sensor.

FIG. 4 is a detailed block diagram of an event processing circuit.

FIG. 5 is a circuit diagram illustrating a configuration example of a logarithmic response unit, a buffer, a differentiator circuit, and a comparator.

FIG. 6A is a diagram illustrating a first example of a multilayer structure of a sensor.

FIG. 6B is a diagram illustrating a second example of the multilayer structure of the sensor.

FIG. 6C is a diagram illustrating a third example of the multilayer structure of the sensor.

FIG. 7 is a block diagram illustrating a photodetection device according to a modification of the first embodiment of the present disclosure.

FIG. 8A is a diagram illustrating a first example of a characteristic of noise events output from an event detection pixel.

FIG. 8B is a diagram illustrating a second example of the characteristic of the noise events output from the event detection pixel.

FIG. 9 is a flowchart illustrating processing content performed by a noise event processing unit.

FIG. 10 is a diagram illustrating a data configuration of an event frame output from the frame-based sensor.

FIG. 11 is a diagram illustrating a plurality of events output from the arbiter-based sensor.

FIG. 12 is a diagram illustrating a data configuration of an accumulated event frame.

FIG. 13 is a diagram illustrating an example of luminance image data output by a luminance image generation unit.

FIG. 14 is a diagram illustrating calibration processing performed by an electronic apparatus including the photodetection device according to the first embodiment of the present disclosure.

FIG. 15 is a block diagram illustrating a schematic configuration of a hybrid sensor according to a comparative example.

FIG. 16 is a diagram illustrating a configuration example of a grayscale pixel.

FIG. 17 is a block diagram illustrating a first example of a photodetection device according to a second embodiment of the present disclosure.

FIG. 18 is a diagram illustrating a first example of a pixel array unit according to the second embodiment of the present disclosure.

FIG. 19 is a block diagram illustrating a second example of the photodetection device according to the second embodiment of the present disclosure.

FIG. 20 is a diagram illustrating a second example of the pixel array unit according to the second embodiment of the present disclosure.

FIG. 21 is a flowchart illustrating imaging processing by a camera including the photodetection device according to the second embodiment of the present disclosure.

FIG. 22 is a block diagram illustrating an example of a schematic configuration of a vehicle control system.

FIG. 23 is an explanatory diagram illustrating an example of installation positions of an outside-vehicle information detection unit and an imaging section.

### MODE FOR CARRYING OUT THE INVENTION

Embodiments of a photodetection device and an electronic apparatus will be described hereinafter with reference to the drawings. Main components of the photodetection device and the electronic apparatus will be mainly described hereinafter, but the photodetection device and the electronic apparatus may have components and functions that are not illustrated or described. The following description is not intended to exclude components and functions that are not illustrated or described.

### First Embodiment

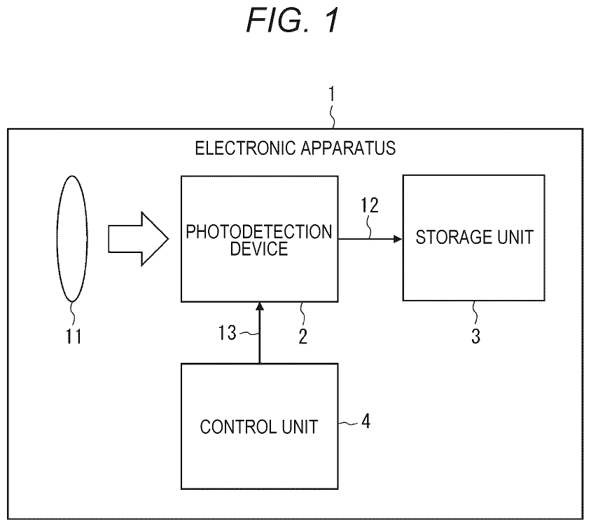

FIG. 1 is a block diagram of an electronic apparatus 1 according to a first embodiment of the present disclosure. The electronic apparatus 1 detects an event based on the amount of change in illuminance of incident light, and includes an imaging lens 11, a photodetection device 2, a storage unit 3, and a control unit 4. The electronic apparatus 1, for example, can be employed as a surveillance camera, a camera mounted on an industrial robot, or the like, but the electronic apparatus 1 has any specific application and configuration.

The imaging lens 11 condenses incident light and guides the condensed incident light to the photodetection device 2. The photodetection device 2 converts the incident light into image data through photoelectric conversion. The photodetection device 2 is, for example, an EVS, and generates image data (hereinafter event image data) including event information. The electronic apparatus 1 executes predetermined signal processing such as image recognition, tracking, or an analysis, and outputs the processed data to the storage unit 3 via a signal line 12. Alternatively, the electronic apparatus 1 may output the event image data to the storage unit 3 as it is. In addition, as will be described later, the photodetection device 2 of FIG. 1 can generate luminance image data including luminance information separately from the event image data. This luminance image data is also called (pseudo) intensity image data.

The storage unit 3 stores the event image data and the luminance image data generated by the photodetection device 2. The storage unit 3 may be disposed in a server or the like connected via a network. The control unit 4 instructs the photodetection device 2 to generate the event image data and the luminance image data via the control line 13. The photodetection device 2 may normally generate the event image data and generate the luminance image data in a case where an explicit instruction is given from the control unit 4. Alternatively, the photodetection device 2 may normally generate the luminance image data and generate the event image data in a case where an explicit instruction is given from the control unit 4.

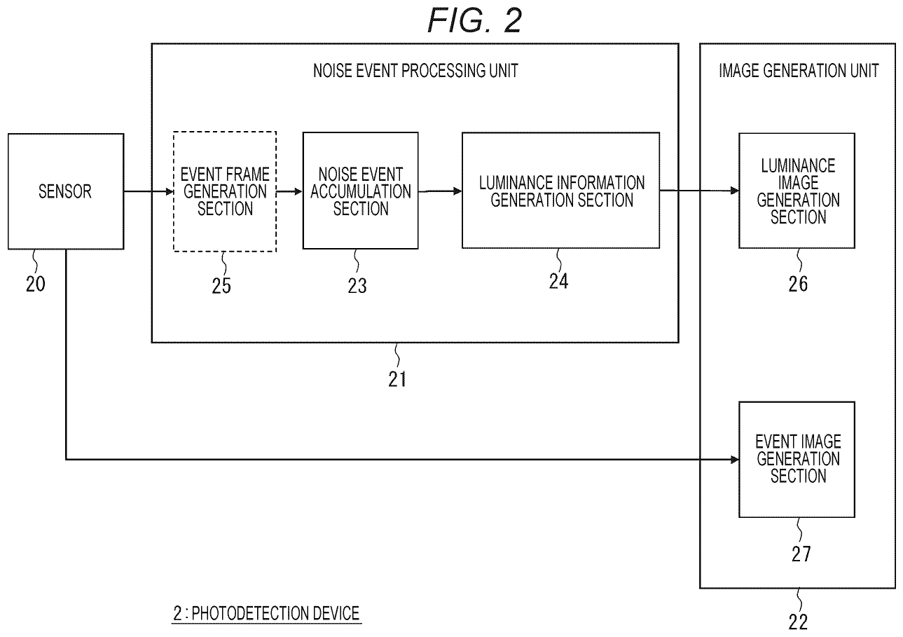

FIG. 2 is a block diagram of the photodetection device 2 according to the first embodiment of the present disclosure. The photodetection device 2 includes a sensor (photodetection element) 20, a noise event processing unit 21, and an image generation unit 22.

The sensor 20 is, for example, an EVS. The sensor 20 includes a plurality of pixels. Each pixel detects an event based on the amount of change in illuminance of incident light. Furthermore, each pixel detects a noise event whose rate of occurrence changes in accordance with the illuminance of the incident light. In the present specification, an event based on the amount of change in illuminance of incident light and a noise event whose rate of occurrence changes in accordance with the illuminance of the incident light will also be collectively referred to as events hereinafter.

Event information detected in a pixel in the sensor 20 is supplied to an event image generation section 27 described later and is also supplied to the noise event processing unit 21. The event information includes a pixel position where the event has been detected, a polarity of the event, a detection time of the event, and the like.

The sensor 20 may be an arbiter-based one or a frame-based one. The arbiter-based sensor asynchronously outputs event information detected in a pixel of the sensor 20. The frame-based sensor detects an event at an arbitrary timing for each pixel, and outputs the detected event information in the form of an event frame in units of frames. Furthermore, the sensor 20 may compress and output the event information.

The noise event processing unit 21 generates luminance information for each pixel on the basis of a noise event generated in each pixel of the sensor 20. Since the rate of occurrence of a noise event changes in accordance with the illuminance of the incident light, the luminance information can be generated for each pixel by counting the number of noise events that have occurred in the pixel. The noise event processing unit 21 includes a noise event accumulation unit (accumulation unit) 23 and a luminance information generation section 24.

The noise event accumulation section 23 accumulates information regarding a plurality of noise events for each of the plurality of pixels. For example, the noise event accumulation section 23 counts the number of noise events that have occurred in each pixel of the sensor 20, and generates an accumulated event frame including a count value of the number of noise events that have occurred in each pixel of the sensor 20. In the accumulated event frame, the count value of the corresponding pixel is updated each time a new noise event occurs.

An event frame generation section 25 may be arranged before the noise event accumulation section 23. The event frame generation section 25 generates an event frame (second event frame) including event information on the basis of noise events supplied from the sensor 20.

The luminance information generation section 24 generates luminance information on the basis of information regarding noise events accumulated in the noise event accumulation section 23 for each of the plurality of pixels. Specifically, the luminance information generation section 24 generates luminance information for each of the plurality of pixels of the sensor 20 on the basis of the number of noise events that have occurred counted in the pixel.

The luminance information generation section 24 generates luminance information under a situation where the illuminance of the incident light incident on the plurality of pixels does not change. In this situation, no event based on the amount of change in the illuminance of the incident light occurs, and noise events based on the illuminance of the incident light are counted in the accumulated event frame. The luminance information generation section 24 converts the count value of noise events of each pixel into luminance information on the basis of the accumulated event frame. The luminance information for each pixel generated by the luminance information generation section 24 is supplied to the image generation unit 22.

The image generation unit 22 includes a luminance image generation section 26 and the event image generation section 27. The luminance image generation section 26 generates luminance image data on the basis of the luminance information for each of the plurality of pixels generated by the luminance information generation section. The luminance image data has a luminance value according to the illuminance for each of the plurality of pixels.

The luminance image data is generated on the basis of the number of noise events that have occurred in each pixel, but since the number of noise events that have occurred changes in accordance with the illuminance of the incident light as described above, the luminance image data can be generated from the number of noise events that have occurred in each pixel.

The event image generation section 27 generates event image data on the basis of a result of detection of events based on the amount of change in the illuminance of the incident light output from the sensor 20. The event image data is, for example, an image indicating presence or absence of detection of events for each pixel. Presence or absence of detection of events may be expressed as, for example, luminance so as to be easily visually recognized by a human, or may be optimized for use in machine learning or the like. In addition, the event image data may have a form in which a frequency or times of occurrence of events can be identified.

The noise event processing unit 21 is provided, for example, in a field programmable gate array (FPGA) outside the sensor 20. Furthermore, the noise event processing unit 21 may be provided inside the sensor 20. Details will be described later.

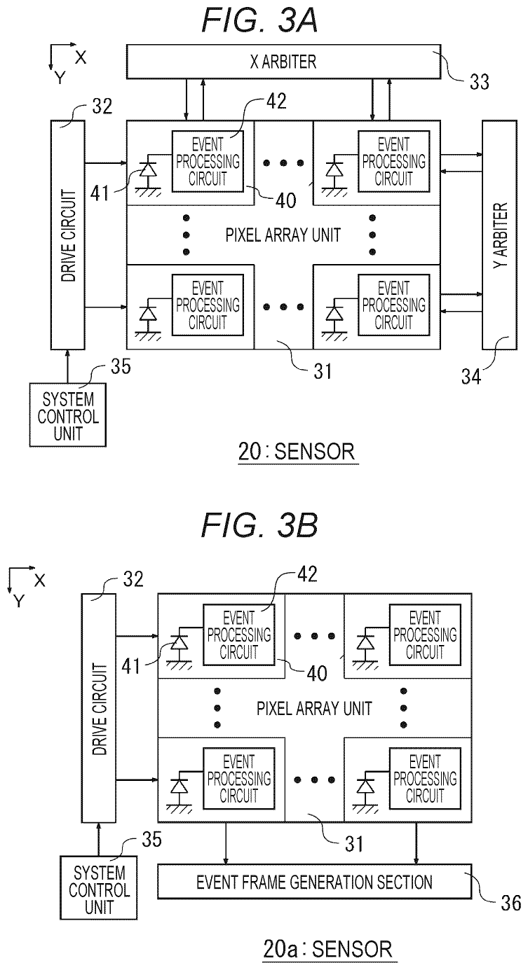

FIGS. 3A and 3B are block diagrams illustrating an internal configuration of the sensor 20 in FIG. 2: FIG. 3A illustrates a block configuration of an arbiter-based sensor, and FIG. 3B illustrates a block configuration of a frame-based sensor. The sensor 20 illustrated in FIG. 3A includes a pixel array unit 31, a drive circuit 32, an X arbiter 33, a Y arbiter 34, and a system control unit 35.

The pixel array unit 31 includes a plurality of event detection pixels (first pixels) 40 arranged in each of a first direction X and a second direction Y. In the present specification, a left-and-right (horizontal) direction in FIG. 3A (FIG. 3B) will be referred to as the first direction X, and an up-and-down (vertical) direction in FIG. 3A (FIG. 3B) will be referred to as the second direction Y. Each event detection pixel 40 includes a photoelectric conversion element 41 and an event processing circuit 42. The photoelectric conversion element 41 is, for example, a photodiode. The event processing circuit 42 detects changes in illuminance of incident light as events on the basis of temporal changes in the amount of electric charge subjected to the photoelectric conversion in the photoelectric conversion element 41.

The drive circuit 32 drives each event detection pixel 40. Each event detection pixel 40 performs processing for detecting an event in accordance with a drive signal from the drive circuit 32.

The X arbiter 33 determines order of priority for outputting events detected by the plurality of event detection pixels 40 arranged along the first direction X. The Y arbiter 34 determines order of priority for outputting events detected by the plurality of event detection pixels 40 arranged along the second direction Y. Each event detection pixel 40 that has detected an event requests the X arbiter 33 and the Y arbiter 34 to output the detected event. The X arbiter 33 and the Y arbiter 34 return, to the event detection pixel 40 that has requested the output of the event, a signal indicating whether or not to permit the output of the event. Upon receiving the output permission of the event, the event detection pixel 40 outputs the event.

The system control unit 35 controls each component of the sensor 20. For example, the system control unit 35 instructs the drive circuit 32 to start or end imaging.

The arbiter-based sensor 20 supplies event information regarding an event asynchronously output by each event detection pixel 40 to the noise event processing unit 21 and the event image generation section 27.

The frame-based sensor 20, on the other hand, outputs the event information detected asynchronously by each event detection pixel 40 in the form of an event frame in units of frames. A sensor 20a illustrated in FIG. 3B includes an event frame generation section 36 instead of the X arbiter 33 and the Y arbiter 34 in FIG. 3A.

The event frame generation section 36 generates an event frame (first event frame) in which the event information detected asynchronously by each event detection pixel 40 is collected in units of frames. The event frame includes a plurality of pieces of event information obtained by sequentially scanning all the pixels of the pixel array unit 31. The event information includes, for example, pixel positions where events have been detected, polarities of the events, detection times of the events, and the like. The event frame generation section 36 supplies the event frame to the noise event processing unit 21 and the event image generation section 27.

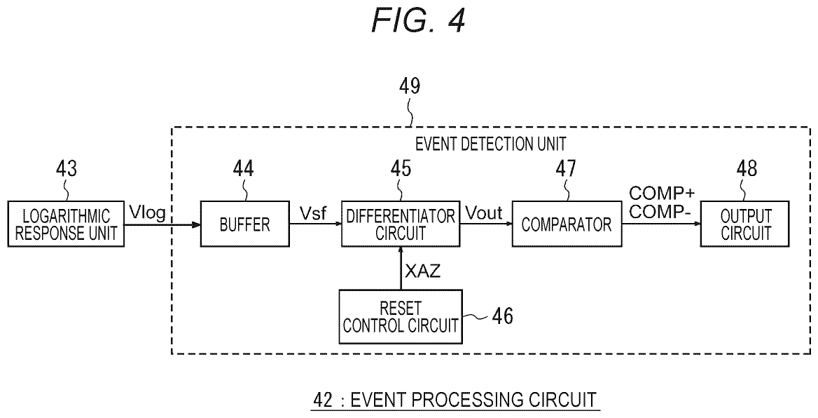

FIG. 4 is a detailed block diagram of the event processing circuit 42. The event processing circuit 42 includes a logarithmic response unit 43, a buffer 44, a differentiator circuit 45, a reset control circuit 46, a comparator 47, and an output circuit 48. The buffer 44, the differentiator circuit 45, the reset control circuit 46, the comparator 47, and the output circuit 48 constitute an event detection unit 49.

The logarithmic response unit 43 performs logarithmic conversion on charges subjected to the photoelectric conversion in the photoelectric conversion element 41 to generate a voltage signal Vlog. A reason for the logarithmic conversion is to widen a dynamic range of the event detection pixel 40 for detecting changes in the luminance information.

The buffer 44 converts a voltage level of the voltage signal Vlog generated by the logarithmic response unit 43 and outputs a voltage signal Vsf.

The differentiator circuit 45 outputs a differential signal Vout indicating the amount of change in voltage per unit time of the voltage signal Vsf output from the buffer 44.

The reset control circuit 46 supplies an auto-zero signal XAZ to the differentiator circuit 45. The auto-zero signal XAZ is a signal requesting resetting of charges accumulated in the differentiator circuit 45. The differentiator circuit 45 is initialized by the auto-zero signal XAZ.

The comparator 47 compares the differential signal Vout with threshold voltages Vhigh and Vlow, and outputs event detection signals COMP+ and COMP−.

The output circuit 48 outputs the event detection signals COMP+ and COMP− output from the comparator 47.

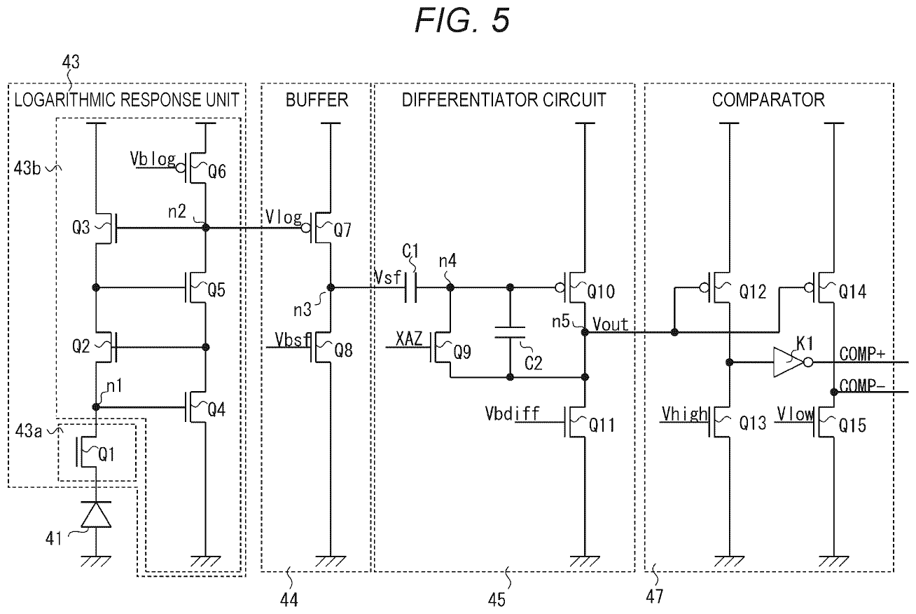

FIG. 5 is a circuit diagram illustrating a configuration example of the logarithmic response unit 43, the buffer 44, the differentiator circuit 45, and the comparator 47 in FIG. 4. The logarithmic response unit 43 includes a transfer section 43a and a charge-to-voltage conversion section 43b.

The photoelectric conversion element 41 includes an anode and a cathode. The anode or the cathode (for example, the cathode) is connected to a source of a transfer transistor Q1 in the transfer section 43a, and the other (for example, the anode) is connected to a predetermined reference voltage node such as a ground voltage.

The transfer section 43a in the logarithmic response unit 43 includes the transfer transistor Q1. The transfer transistor Q1 is used to switch transfer of photocharges. The source of the transfer transistor Q1 is connected to the cathode of the photoelectric conversion element 41. The transfer transistor Q1 is turned on in a case where, for example, a high-level transfer signal is applied to a gate thereof. A drain of the transfer transistor Q1 is connected to an input node n1 of the charge-to-voltage conversion section 43b.

The charge-to-voltage conversion section 43b in the logarithmic response unit 43 converts charges accumulated in the photoelectric conversion element 41 into a voltage. The charge-to-voltage conversion section 43b includes transistors Q2 to Q6. As the transistors Q2 to Q5, for example, N-channel metal-oxide-semiconductor (NMOS) transistors are used. As the transistor Q6, for example, a P-channel metal-oxide-semiconductor (PMOS) transistor is used.

The transistors Q2 and Q3 are cascode-connected between a power supply voltage node and the transfer transistor Q1. A source of the transistor Q2 is connected to the drain of the transistor Q1 and a gate of the transistor Q4. A gate of the transistor Q2 is connected to a drain of the transistor Q4 and a source of the transistor Q5. A drain of the transistor Q2 is connected to a source of the transistor Q3 and a gate of the transistor Q5. A drain of the reset transistor Q3 is connected to the power supply voltage note. A gate of the transistor Q3 is connected to an output node n2 of the charge-to-voltage conversion section 43b, a drain of the transistor Q5, and a drain of the transistor Q6.

The transistor Q4 and the transistor Q5 are cascode-connected between the node n2 and a reference voltage (ground) node. The source of the transistor Q4 is connected to the reference voltage (ground) node. The transistor Q5 is disposed between the transistor Q4 and the transistor Q6.

A source of the transistor Q6 is connected to the power supply voltage node, and a bias voltage Vblog is applied to a gate thereof. The transistor Q6 adjusts a voltage level at the output node n2 using a voltage level of the bias voltage Vblog.

The voltage signal Vlog obtained through the logarithmic conversion by the charge-to-voltage conversion section 43b is input to the buffer 44. The buffer 44 includes a transistor Q7 and a transistor Q8 cascode-connected between the power supply voltage node and the reference voltage (ground) node. As the transistor Q7, for example, a PMOS transistor is used. As the transistor Q8, for example, an NMOS transistor is used.

The transistor Q7 in the buffer 44 is included in a source follower circuit. A pixel voltage Vsf according to the voltage signal Vlog output from the charge-to-voltage conversion section 43b is output from the buffer 44. The voltage signal Vlog is input to a gate of the transistor Q7 from the output node n2 of the charge-to-voltage conversion section 43b. A source of the transistor Q7 is connected to the power supply voltage node. A drain of the transistor Q7 is connected to a drain of the transistor Q8 and the differentiator circuit 45 via an output node n3 of the buffer 44.

A source of the transistor Q8 is connected to the reference voltage (ground) node. A bias voltage Vbsf is applied to a gate of the transistor Q8. The transistor Q8 adjusts a voltage level at the output node n3 in accordance with a voltage level of the bias voltage Vbsf.

The pixel voltage Vsf output from the buffer 44 is input to the differentiator circuit 45. The buffer 44 can improve driving force of the pixel voltage Vsf. Furthermore, by providing the buffer 44, it is possible to secure isolation for preventing noise generated in a case where the differentiator circuit 45 at a subsequent stage performs a switching operation from being transmitted to the charge-to-voltage conversion section 43b.

The differentiator circuit 45 generates a differential signal Vout in accordance with a change in the pixel voltage Vsf output from the buffer 44. The differentiator circuit 45 includes a capacitor C1 and transistors Q9 to Q11. For the transistor Q9 and Q11, for example, NMOS transistors are used, and for the transistor Q10, for example, a PMOS transistor is used.

The capacitor C1 is disposed between a connection node n4 of a source of the transistor Q9 and a gate of the transistor Q10 and the output node n3 of the buffer 44. The capacitor C1 accumulates charges on the basis of the pixel voltage Vsf output from the buffer 44. The capacitor C1 supplies charges according to the amount of change in the pixel voltage Vsf obtained by temporally differentiating the pixel voltage Vsf to the gate of the transistor Q10.

The capacitor C2 is connected between the gate of the transistor Q10 and a drain of the transistor Q11.

The transistor Q9 switches whether or not to short-circuit the gate and the drain of the transistor Q10 in accordance with the auto-zero signal XAZ. The auto-zero signal XAZ is a signal requesting initialization, and for example, changes from a high level to a low level every time an event detection signal described later is output from the event detection pixel 40. When the auto-zero signal XAZ changes to the low level, the transistor Q9 is turned on, the differential signal Vout becomes an initial value, and charges of the capacitor C2 are initialized.

A source of the transistor Q11 is connected to the reference voltage (ground) node, and a bias voltage Vbdiff is applied to a gate of the transistor Q11. The transistor Q11 adjusts a voltage level at an output node n5 of the differentiator circuit 45 in accordance with a voltage level of the bias voltage Vbdiff.

The transistor Q10 and the transistor Q11 function as an inverter circuit having the connection node n4 on a gate side of the transistor Q10 as an input node and the connection node n5 between the transistor Q10 and the transistor Q11 as an output node.

As described above, the differentiator circuit 45 detects the amount of change in the pixel voltage Vsf through a differential operation. The amount of change in the pixel voltage Vsf indicates the amount of change in illuminance of incident light on the event detection pixel 40. The differentiator circuit 45 supplies the differential signal Vout to the comparator 47 via the output node n5.

The comparator 47 performs a comparison operation for comparing the differential signal Vout with a threshold voltage. The comparator 47 detects an event indicating that an absolute value of the amount of change in the illuminance of the incident light has exceeded the threshold voltage on the basis of a result of the comparison operation, and outputs an event detection signal COMP+ and an event detection signal COMP−. The comparator 47 includes transistors Q12 to Q15 and an inverter K1. As the transistors Q12 and Q14, for example, PMOS transistors are used. Furthermore, as the transistors Q13 and Q15, for example, NMOS transistors are used.

The transistors Q12 and Q13 are vertically stacked on each other between the power supply voltage node and the reference voltage (ground) node. A source of the transistor Q12 is connected to the power supply voltage node. A drain of the transistor Q12 is connected to the inverter K1 and a drain of the transistor Q13. A source of the transistor Q13 is connected to the reference voltage (ground) node. The differential signal Vout of the differentiator circuit 45 is applied to a gate of the transistor Q12. A threshold voltage Vhigh is applied to a gate of the transistor Q13.

The transistors Q12 and Q13 compare the differential signal Vout with the threshold voltage Vhigh. Specifically, when the differential signal Vout of the differentiator circuit 45 is lower than the threshold voltage Vhigh, the transistor Q12 is turned on, and the event detection signal COMP+ output from the drain of the transistor Q12 via the inverter K1 is at the low level.

The transistors Q14 and Q15 are vertically stacked on each other between the power supply voltage node and the reference voltage (ground) node. A source of the transistor Q14 is connected to the power supply voltage node. A drain of the transistor Q14 is connected to an output node of the comparator 47 and a drain of the transistor Q15. The differential signal Vout of the differentiator circuit 45 is applied to a gate of the transistor Q14. A threshold voltage Vlow is applied to a gate of the transistor Q15.

The transistors Q14 and Q15 compare the differential signal Vout with the threshold voltage Vlow. Specifically, when the differential signal Vout of the differentiator circuit 45 is higher than the threshold voltage Vlow, the transistor Q14 is turned off, and the event detection signal COMP− output from the drain of the transistor Q14 is at the low level.

The event detection pixel 40 can detect an increase and a decrease in the illuminance of the incident light as an event. In a case where the illuminance of the light incident on the event detection pixel 40 increases, charges (hereinafter photocharges) are generated by the photoelectric conversion element 41 in accordance with the illuminance of the incident light, and the voltage at the input node n1 connected to the cathode of the photoelectric conversion element 41 decreases. As the voltage at the input node n1 decreases, the output voltage Vlog of the charge-to-voltage conversion section 43b increases, and the pixel voltage Vsf of the buffer 44 also decreases. When the differential signal Vout output from the differentiator circuit 45 increases in accordance with the amount of decrease in the pixel voltage Vsf and exceeds the threshold voltage Vhigh, the low-level event detection signal COMP+ is output. That is, the low-level event detection signal COMP+ indicates that the amount of increase in the illuminance of the incident light has exceeded a threshold determined from the threshold voltage Vhigh.

Similarly, when the illuminance of the light incident on the event detection pixel 40 decreases and the differential signal Vout output from the differentiator circuit 45 decreases and falls below the threshold voltage Vlow, the low-level event detection signal COMP− is output. That is, the low-level event detection signal COMP− indicates that the amount of decrease in the illuminance of the incident light fallen below the threshold determined from the threshold voltage Vlow.

In the present specification, detection of either the low-level event detection signal COMP+ or the low-level event detection signal COMP− will be referred to as detection of an event. In addition, an event has polarity information indicating whether the luminance of the incident light is positive or negative. In a case where the low-level event detection signal COMP+ is detected, the polarity is positive, and in a case where the low-level event detection signal COMP− is detected, the polarity is negative. In addition, in the present specification, the event detection signals COMP+ and COMP− will be collectively referred to as event detection signals COMP.

The event detection pixel 40 need not detect both the event detection signal COMP+ and the event detection signal COMP−, and may detect one of the two signals. For example, the transistors Q14 and Q15 may be removed from the comparator 47, and only the event detection signal COMP+ may be output. In this case, only an increase in the illuminance of the light incident on the photoelectric conversion element 41 is detected.

Similarly, the transistors Q12 and Q13 and the inverter K1 may be removed from the comparator 47. In this case, the event detection pixel 40 detects only a decrease in the illuminance of the light incident on the photoelectric conversion element 41, and outputs the event detection signal COMP−.

As described above, the event detection pixel 40 detects the low-level event detection signal COMP as the illuminance of the incident light increases or decreases. The low-level event detection signal COMP, however, might be detected due to factors other than an increase or a decrease in the illuminance of the incident light. For example, the transistors Q2 and Q4 in the charge-to-voltage conversion section 43b constitute a loop circuit. The loop circuit becomes a negative feedback circuit under a predetermined condition of illuminance or the like, and the voltage signal Vlog is oscillated. As a result, the low-level event detection signal COMP might be detected. In the present specification, detection of the low-level event detection signal COMP that is not caused by an increase or decrease in the illuminance of the incident light will be referred to as detection of a noise event.

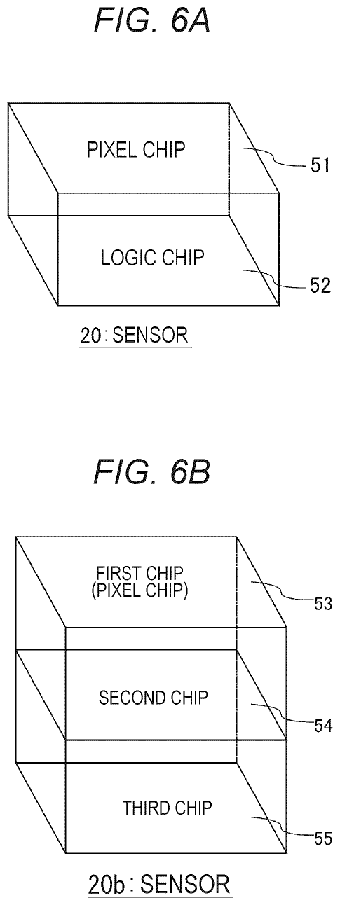

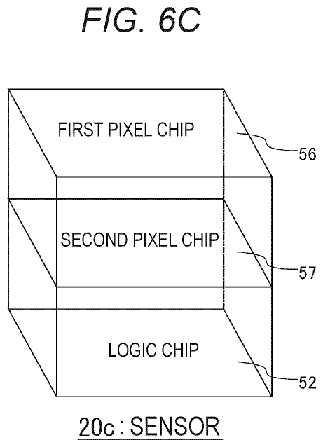

The sensor 20 can also be implemented as, for example, a two-layer chip. FIG. 6A is a diagram illustrating a first example of a multilayer structure of the sensor 20. This sensor 20 includes a pixel chip 51 and a logic chip 52 stacked on the pixel chip 51. Those chips are joined together by vias or the like. Note that they can also be joined together by Cu—Cu bonding or bumps instead of the vias.

In the pixel chip 51, for example, the photoelectric conversion element 41 and a part of the event processing circuit 42 (for example, the transfer section 43a and the charge-to-voltage conversion section 43b) are arranged. In the logic chip 52, for example, a remaining part (for example, the event detection unit 49) of the event processing circuit 42, the drive circuit 32, and the system control unit 35, and (in the case of the arbiter-based sensor) the X arbiter 33 and the Y arbiter 34 or (in the case of the frame-based sensor) the event frame generation section 36 are arranged.

The sensor 20 may be implemented as a multilayer chip including three or more layers, instead. FIG. 6B is a diagram illustrating a second example of the multilayer structure of the sensor 20. A first chip (pixel chip) 53, a second chip 54, and a third chip 55 are stacked on one another in a sensor 20a in FIG. 6B. For example, the photoelectric conversion element 41 and the transfer section 43a are arranged on the first chip 53. For example, the charge-to-voltage conversion section 43b is arranged on the second chip 54. Similarly to the logic chip 52 of FIG. 6A, the event detection unit 49, the drive circuit 32, the system control unit 35, the X arbiter 33, the Y arbiter 34, and the event frame generation section 36 are arranged on the third chip 55.

The sensor 20b in FIG. 6B has a configuration in which the charge-to-voltage conversion section 43b is removed from the first chip 53 and disposed on the second chip 54. As a result, even in a case where chip area is miniaturized, area of the photoelectric conversion element 41 can be secured in the first chip 53, and area of the charge-to-voltage conversion section 43b can be secured in the second chip 54.

The sensor 20 may have a configuration in which two or more pixel chips are stacked, instead. FIG. 6C is a diagram illustrating a third example of the multilayer structure of the sensor 20. In the sensor 20c of FIG. 6C, a first pixel chip 56 and a second pixel chip 57 are stacked instead of the pixel chip 51 of FIG. 6A. In the second pixel chip 57, event detection pixels 40 that react to infrared light are arranged. In the first pixel chip 56, CIS pixels described later that react to visible light are arranged. In this case, the first pixel chip 56 needs to include a material that transmits infrared light.

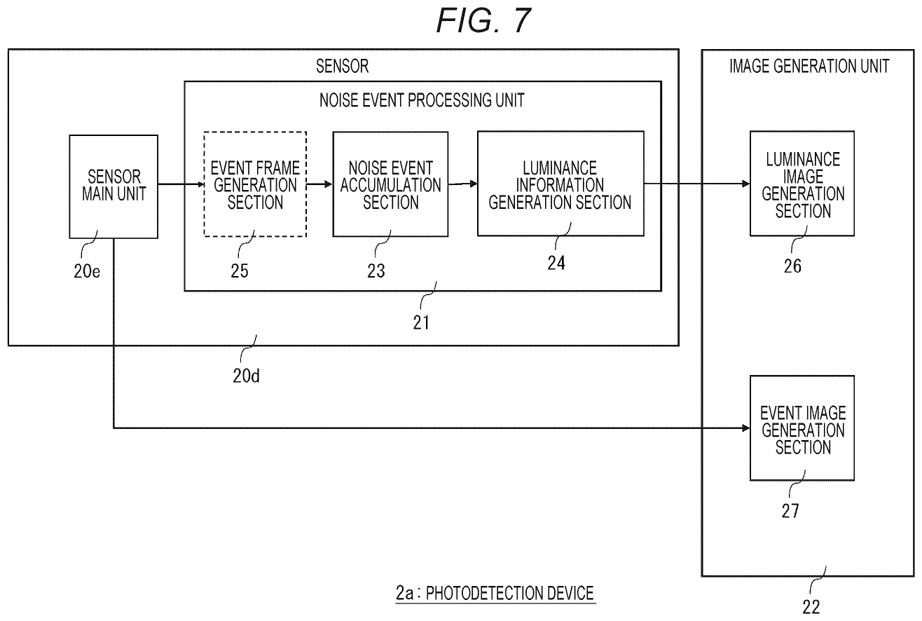

Although FIG. 2 illustrates an example in which the noise event processing unit 21 is provided separately from the sensor 20, the noise event processing unit 21 may be provided inside the sensor 20, instead. FIG. 7 is a block diagram illustrating a photodetection device 2 according to a modification of the first embodiment of the present disclosure. A sensor 20d in a photodetection device 2a of FIG. 7 includes a sensor main unit 20e and a noise event processing unit 21. The sensor main unit 20e has a block configuration similar to that in FIG. 3A or 3B.

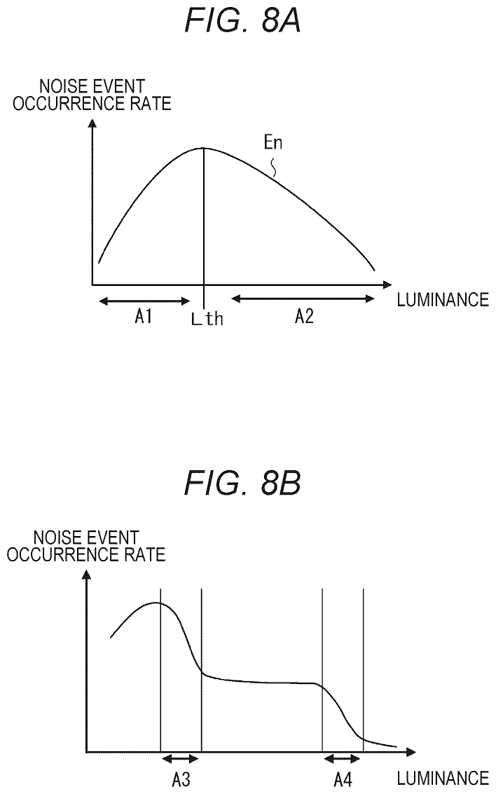

FIG. 8A is a diagram illustrating a first example of a characteristic of noise events output from the event detection pixel 40, where a horizontal axis represents illuminance of incident light and a vertical axis represents a rate of occurrence of noise events. As illustrated in FIG. 8A, a rate En of occurrence of noise events in the sensor 20 increases or decreases in accordance with the illuminance. In FIG. 8A, the rate En of occurrence of noise events monotonously increases in a first illuminance range A1 until the illuminance reaches a predetermined reference value Lth. The rate En of occurrence of noise events monotonously decreases in a second illuminance range A2 where the illuminance has exceeded the predetermined reference value Lth.

In a case where the illuminance of the light incident on the sensor 20 increases or decreases within the first illuminance range A1 (or within the second illuminance range A2), the illuminance can be uniquely determined from the rate En of occurrence of noise events. Using this, the luminance information generation section 24 can generate luminance information corresponding to the illuminance of the light incident on the event detection pixel 40. That is, the luminance information generation section 24 can generate the luminance information in an illuminance range (for example, the first illuminance range A1) in which the rate of occurrence of noise events monotonously changes.

The rate of occurrence of noise events in the sensor 20 might have a more complex characteristic than in FIG. 8A. FIG. 8B is a diagram illustrating a second example of the characteristic of noise events output from the event detection pixel 40. For example, as illustrated in FIG. 8B, even in a case where there is a plurality of illuminance ranges in which the rate of occurrence of noise events monotonously decreases in accordance with an increase in the illuminance (for example, a third illuminance range A3 and a fourth illuminance range A4 in FIG. 8B) and the illuminance increases or decreases within each of the illuminance ranges in which the rate of occurrence of noise events monotonously decreases, the illuminance can be uniquely determined from the rate of occurrence of noise events. The same applies to a case where there is a plurality of illuminance ranges in which the rate of occurrence of noise events monotonously increases in accordance with an increase in the illuminance.

As described above, each event detection pixel 40 detects noise events at a rate of occurrence according to the illuminance regardless of whether or not the illuminance of the incident light changes. For example, in a case where the illuminance of the incident light is within the first illuminance range A1, the higher the illuminance, the higher the rate of occurrence of noise events in each event detection pixel 40. By counting the number of noise events that have occurred and converting the count value into luminance information, luminance information can be generated from the noise events. Furthermore, luminance image data can be generated from the luminance information regarding each event detection pixel 40.

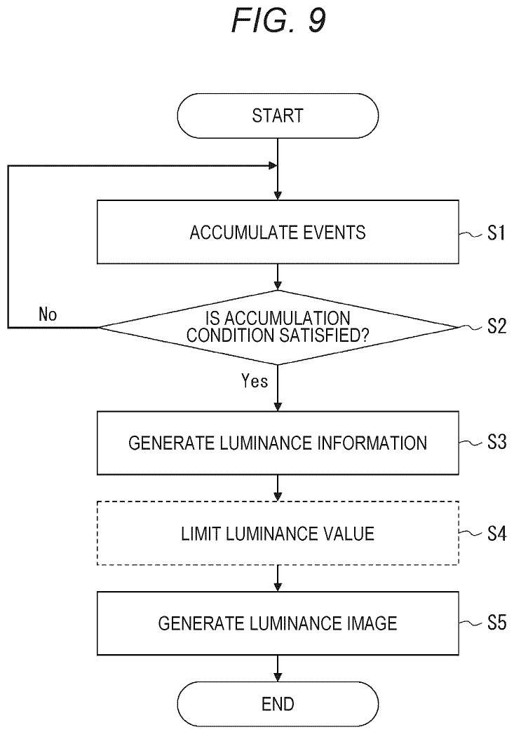

FIG. 9 is a flowchart illustrating a processing procedure performed by the noise event processing unit 21. The flowchart of FIG. 9 corresponds to the photodetection device 2 having the block configuration of FIG. 2.

First, the noise event accumulation section 23 in the noise event processing unit 21 accumulates noise events output from each event detection pixel 40 in the sensor 20 to generate an accumulated event frame (step S1). More specifically, the noise event accumulation section 23 counts, for each event detection pixel 40, the number of noise events that have occurred output from the event detection pixel 40. An aggregate of the number of counts corresponding to all the event detection pixels 40 of the sensor 20 is the accumulated event frame. Each time a new noise event occurs, the number of counts at a corresponding pixel is updated in the accumulated event frame.

Since a noise event is output from each event detection pixel 40 under a situation where the illuminance does not change, the noise event is originally irrelevant to the polarity of a luminance change. When a noise event is detected, the event detection signal COMP+ or COMP− output from the sensor 20 capable of detecting the polarity of the event indicates the noise event. At this time, the noise event accumulation section 23 may count the number of noise events that have occurred on the basis of any one of the event detection signals COMP+ and COMP−, or may count the number of noise events that have occurred on the basis of both.

The noise event accumulation section 23 determines whether or not an accumulation condition is satisfied each time the number of counts is newly updated (step S2).

Various accumulation conditions are conceivable. For example, the noise event accumulation section 23 may set, as the accumulation condition, a case where a total value of the number of noise events that have occurred counted for the plurality of event detection pixels 40 reaches a predetermined value. Alternatively, the accumulation condition may be a case where either a maximum value of the number of noise events that have occurred in the plurality of event detection pixels 40 or an average value of the number of noise events that have occurred in the plurality of event detection pixels 40 reaches a predetermined value.

The noise event accumulation section 23 repeats the processing in steps S1 and S2 until the accumulation condition is satisfied, and updates the count value of the number of noise events that have occurred in each event detection pixel 40 in the accumulated event frame.

The processing (steps S1 and S2) by the noise event accumulation section 23 differs depending on whether the sensor 20 is frame-based or arbiter-based. Details will be described later.

When the noise events accumulated in the noise event accumulation section 23 satisfy the accumulation condition in step S2, the luminance information generation section 24 generates luminance information for each event detection pixel 40 (step S3). In step S3, the number of counts of each event detection pixel 40 accumulated in the accumulated event frame is converted into a luminance value representing luminance information.

The luminance information generation section 24 may limit the luminance value generated in step S3 (step S4). The event detection pixels 40 include pixels in which an event is likely to occur and pixels in which an event is unlikely to occur. In the pixels in which an event is likely to occur, white spots might occur in the luminance image data. Therefore, when noise events are accumulated in step S1, the luminance information generated in step S3 may be limited to a predetermined luminance value for event detection pixels 40 in which the number of noise events that have occurred and been accumulated has reached a saturation value. As a result, it is possible to prevent occurrence of white spots at pixel positions where an event is likely to occur, and to improve image quality of the luminance image data.

In the pixels in which an event is unlikely to occur, on the other hand, black spots might occur in the luminance image data. The luminance information generation section 24 may limit the luminance information to a predetermined luminance value even for the pixel in which an event is unlikely to occur, and prevent occurrence of black spots. That is, the luminance information generated in step S3 may be limited to a predetermined luminance value for event detection pixels 40 in which the number of noise events that have occurred and been accumulated does not reach the predetermined threshold.

The luminance image generation section 26 in the image generation unit 22 generates luminance image data including the luminance value generated in step S3 or S4 for each event detection pixel 40 (step S5).

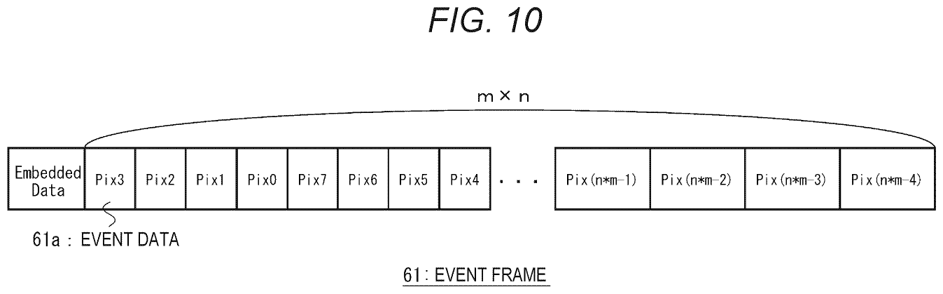

FIG. 10 is a diagram illustrating a data configuration of an event frame output from the frame-based sensor 20. In a case where the sensor 20 is frame-based, the event frame generation section 36 in the sensor 20 outputs an event frame 61 illustrated in FIG. 10 at a predetermined timing. The event frame 61 includes, for each event detection pixel 40, a plurality of pieces of event data 61a including information regarding noise events detected asynchronously by the plurality of event detection pixels 40. For example, in a case where m event detection pixels 40 are arranged in the first direction X of the pixel array unit 31 and n event detection pixels 40 are arranged in the second direction Y, the event frame 61 includes m×n pieces of event data 61a. Note that the arrangement of the event data 61a is not limited to that illustrated in FIG. 10. Since each piece of event data 61a in the event frame 61 is arranged at a corresponding pixel position, the event data 61a need not include information regarding the pixel position, and only needs to include information regarding whether or not a noise event has occurred.

The frame-based sensor 20 supplies information regarding noise events to the noise event processing unit 21 in units of the event frame 61. The noise event accumulation section 23 in the noise event processing unit 21 counts the number of noise events that have occurred in each event detection pixel 40 on the basis of a corresponding piece of event data 61a in the event frame 61 transmitted from the sensor 20 to generate an accumulated event frame.

In a case where the sensor 20 is frame-based, the noise event accumulation section 23 may set, as the accumulation condition, a case where the total number of event frames 61 transmitted from the sensor 20 reaches a predetermined number.

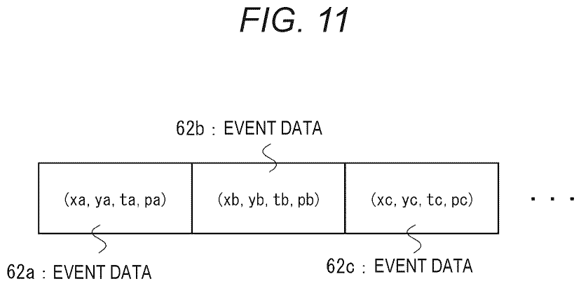

FIG. 11 is a diagram illustrating a plurality of events output from the arbiter-based sensor 20. When the sensor 20 is arbiter-based, each of the plurality of event detection pixels 40 in the sensor 20 detects noise events asynchronously. FIG. 11 illustrates an example in which an arbiter-based sensor outputs, for example, event data 62a, 62b, and 62c.

The event data 62a, 62b, and 62c each includes the following information.
xa, xb, and xc: X addresses indicating detection positions (for example, pixel positions) of noise events.
ya, yb, and yc: Y addresses indicating detection positions (for example, pixel positions) of noise events.
ta, tb, and tc: time information (timestamps) indicating detection times of noise events.
pa, pb, and pc: polarity information regarding noise events.

In the arbiter-based sensor 20, a plurality of pieces of event data is asynchronously supplied to the noise event accumulation section 23. The noise event accumulation section 23 updates the count values of the number of noise events that have occurred corresponding to pixel positions of the event data, and generates accumulated event frame data.

In a case where the sensor 20 is arbiter-based, the noise event accumulation section 23 may set, as the accumulation condition, a case where a predetermined time has elapsed since the sensor 20 started detecting noise events.

Alternatively, the noise event processing unit 21 may include the event frame generation section 25 that generates an event frame on the basis of event data asynchronously output from the arbiter-based sensor 20. In this case, the event frame generation section 25 generates an event frame on the basis of event data output from an arbiter-based sensor at predetermined time intervals.

The event frame generation section 25 performs processing similar to that by the event frame generation section 36 in FIG. 3B. Therefore, processing for accumulating noise events performed by the noise event accumulation section 23 is also similar to steps S1 and S2 in FIG. 9. In addition, the noise event accumulation section 23 may set, as the accumulation condition, a case where the total number of event frames generated by the event frame generation section 25 reaches a predetermined value.

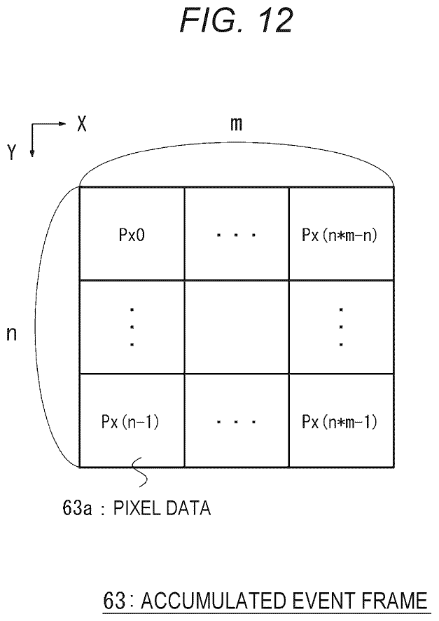

FIG. 12 is a diagram illustrating a data configuration of an accumulated event frame. The accumulated event frame 63 is divided into a plurality of pieces of pixel data 63a in association with the event detection pixels 40 of the sensor 20. That is, in a case where m event detection pixels 40 are arranged in the first direction X of the pixel array unit 31 and n event detection pixels 40 are arranged in the second direction Y, m pieces of pixel data 63a are arranged in the first direction X and n pieces of pixel data 63a are arranged in the second direction Y also in the accumulated event frame 63.

In each piece of pixel data 63a, a count value of the number of noise events that have occurred in a corresponding event detection pixel 40 is arranged. In the accumulated event frame 63, the count value of a corresponding piece of pixel data 63a is updated each time a new noise event occurs until the accumulation condition is satisfied.

The noise event accumulation section 23 may generate an accumulated event frames of two-dimensional arrangement illustrated in FIG. 12 from the event frame data of one-dimensional arrangement illustrated in FIG. 10. In addition, the event frame generation section 25 may convert the event frame data of one-dimensional arrangement illustrated in FIG. 10 into event frame data of two-dimensional arrangement and supply the event frame data to the noise event accumulation section 23.

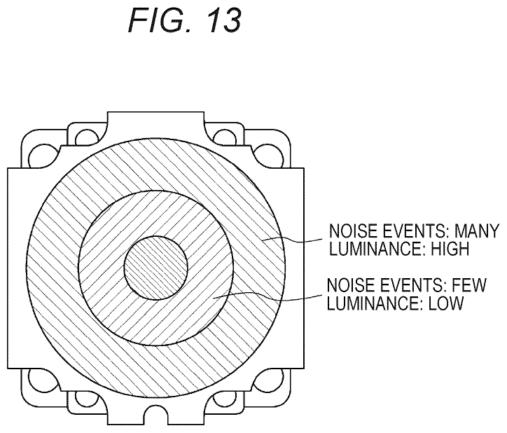

FIG. 13 is a diagram illustrating an example of luminance image data output by the luminance image generation section 26. As illustrated in FIG. 13, the higher the rate of occurrence of noise events, the higher the luminance of an image obtained.

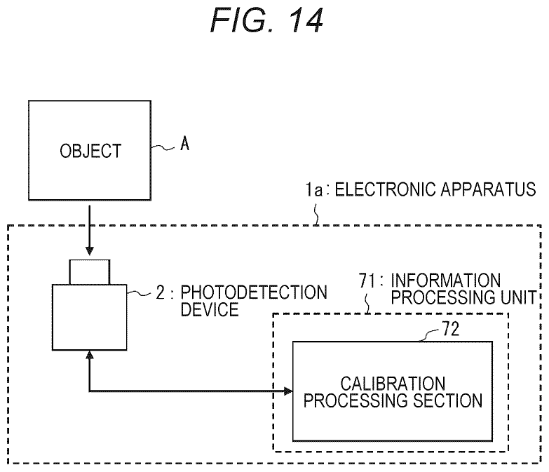

FIG. 14 is a diagram illustrating calibration processing performed by an electronic apparatus including the photodetection device 2 according to the first embodiment of the present disclosure. An electronic apparatus 1a illustrated in FIG. 14 performs processing for calibrating the photodetection device 2 on the basis of luminance image data regarding an object A generated by the photodetection device 2. The electronic apparatus 1a includes a photodetection device 2 and an information processing unit 71. The information processing unit 71 includes a calibration processing section 72. The calibration processing section 72 performs the processing for calibrating the photodetection device 2 on the basis of the luminance image data.

The photodetection device 2 generates luminance image data regarding the object A on the basis of noise events generated in the event detection pixel 40 of the sensor 20, and supplies the luminance image data to the calibration processing section 72. The calibration processing section 72 performs the processing for calibrating the photodetection device 2 on the basis of the luminance image data. The calibration processing includes, for example, processing for correcting distortion of event image data output from the photodetection device 2, adjustment of an angle of view, alignment when attaching a lens to the sensor, adjustment of a lens angle, adjustment of a focal length, and the like.

In order to perform the calibration processing with the existing EVS sensor, it is necessary to change the luminance of the object A by performing processing such as moving the object A or changing intensity of light radiated onto the object A. In addition, in order to grasp an appearance of the object A, it is necessary to provide an image sensor that generates grayscale image data separately from the EVS sensor that generates event image data, so that the configuration of the electronic apparatus becomes complicated and a device cost increases. In the electronic apparatus 1a including the photodetection device 2 according to the present embodiment, on the other hand, since luminance image data can be generated by the photodetection device 2 that originally generates event image data, the electronic apparatus 1a can be reduced in size and cost.

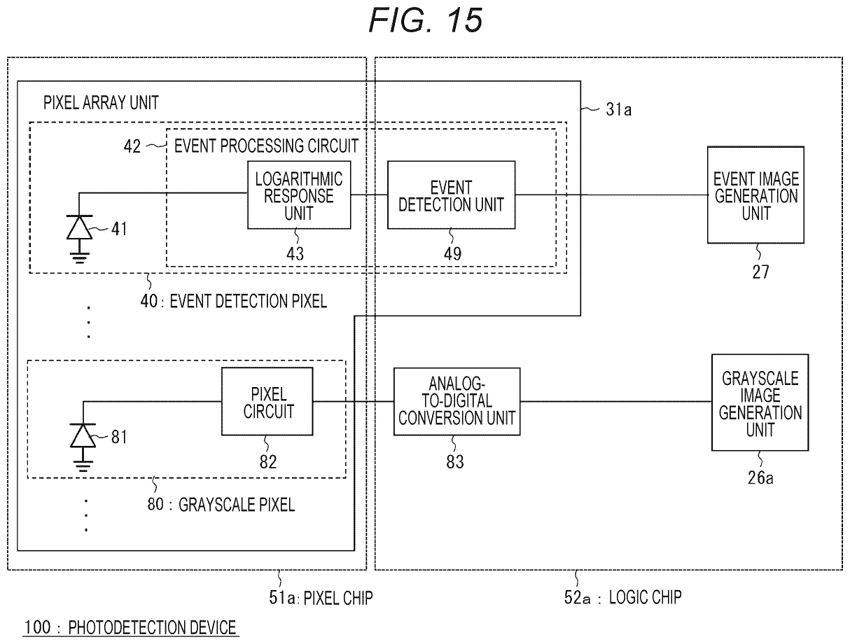

As described above, in order to generate luminance image data using an existing sensor including event detection pixels, it is necessary to prepare a hybrid sensor including grayscale pixels in addition to the event detection pixels. FIG. 15 is a block diagram illustrating a schematic configuration of a hybrid sensor according to a comparative example. A photodetection device 100 illustrated in FIG. 15 includes a plurality of event detection pixels 40, a plurality of grayscale pixels 80, an analog-to-digital conversion unit 83, a grayscale image generation unit 26a, and an event image generation section 27 in a pixel array unit 31a.

Each grayscale pixel 80 includes a photoelectric conversion element 81 and a pixel circuit 82. The pixel circuit 82 generates a pixel signal on the basis of charges accumulated in the photoelectric conversion element 81. The analog-to-digital conversion unit 83 converts a pixel signal into a digital pixel signal. The grayscale image generation unit 26a generates grayscale image data on the basis of the digital pixel signal. This grayscale image data is also called intensity image data.

The photoelectric conversion element 41, the photoelectric conversion element 81, the logarithmic response unit 43, and the pixel circuit 82 are arranged on a pixel chip 51a. The event detection unit 49, the analog-to-digital conversion unit 83, the grayscale image generation unit 26a, and the event image generation section 27 are arranged on a logic chip 52a.

The photodetection device 100 in the comparative example uses some pixels in the pixel array unit 31a for generation of event image data, and uses remaining pixels for generation of grayscale image data. For this reason, resolution of both the event image data and the grayscale image data decreases. In order to increase the resolution of the event image data and the grayscale image data, it is necessary to increase the number of pixels in the pixel array unit 31a, which makes it difficult to reduce the size and cost of the photodetection device 100.

Furthermore, in the hybrid sensor illustrated in FIG. 15, it is necessary to perform binning processing for combining the event data generated by the event detection pixels 40 and the pixel data generated by the grayscale pixels 80, and post-processing after imaging takes time and effort.

Furthermore, in order to perform analog-to-digital conversion on pixel signals output from the grayscale pixels 80, the analog-to-digital conversion unit 83 is required. Therefore, area of the logic chip 52a increases.

As a modification of the photodetection device 100 in FIG. 15, a configuration in which the event processing circuit 42 and the pixel circuit 82 share one photoelectric conversion element is conceivable. In this case, a switch for switching between supplying charges subjected to photoelectric conversion by the photoelectric conversion element to the event processing circuit 42 and supplying charges to the pixel circuit 82 and a switching circuit for the switch are required, and a pixel configuration becomes complicated. In addition, even in a case where the photoelectric conversion element is shared, since the event processing circuit 42 and the pixel circuit 82 need to be provided for each pixel, the resolution of the event image data and the grayscale image data cannot be improved as in FIG. 15. Furthermore, the analog-to-digital conversion unit 83 is also required at s subsequent stage of the pixel circuit 82 as in FIG. 15. Moreover, the binning processing is required as in FIG. 15.

The photodetection device 2 in the present disclosure can generate luminance image data in addition to event image data using the event detection pixels 40. As a result, the configuration of the pixels can be simplified, and luminance image data with higher resolution than that achieved by an existing hybrid sensor can be generated at low cost. In addition, since the photodetection device 2 in the present disclosure does not have a hybrid configuration, there is no need to perform the binning processing, and signal processing after detection of an event can be simplified.

In addition, since the photodetection device 2 does not include the grayscale pixels 80, the analog-to-digital conversion unit 83 can be omitted. As a result, area of the pixel chip 51 and the logic chip 52 can be reduced as compared with the photodetection device 100 in the comparative example.

In addition, the photodetection device 2 can generate grayscale image data from pixels for an EVS (event detection pixels 40). In this case, the photodetection device 2 can generate grayscale image data without using analog-to-digital conversion. As a result, the photodetection device 2 can generate grayscale image data with lower power consumption than the photodetection device 100 in the comparative example using pixels for a CIS (grayscale pixels 80).

As described above, the first embodiment of the present disclosure focuses on the property of the EVS sensor that outputs the number of noise events according to the illuminance even if there is no luminance change. The photodetection device 2 according to the first embodiment of the present disclosure counts the number of noise events that have occurred in each pixel, and generates luminance information for each pixel on the basis of a result of the counting. As a result, luminance image data can be generated only by the EVS sensor. Therefore, it is not necessary to provide an image sensor or the like such as a CIS sensor in addition to the EVS sensor for calibration of the EVS camera, tracking of a still object, obtaining of a background image of a surveillance camera, and the like, and it is possible to achieve downsizing of the photodetection device, cost reduction, and low power consumption in generation of a grayscale image.

### second Embodiment

Although it has been described that the luminance image data can be generated only by the event detection pixels without forming the photodetection device 2 in the hybrid configuration in the first embodiment, the photodetection device 2 may be formed in the hybrid configuration and the grayscale image data may be generated by the grayscale pixels 80 separately from the luminance image data generated by the event detection pixels 40, instead.

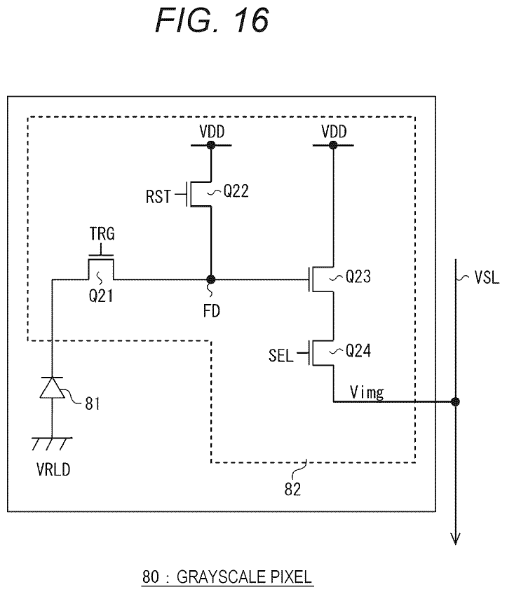

FIG. 16 is a diagram illustrating a configuration example of the grayscale pixel 80. The grayscale pixel (second pixel) 80 illustrated in FIG. 16 outputs a pixel signal based on illuminance of incident light.

The grayscale pixel 80 includes a photoelectric conversion element 81 and a pixel circuit 82. The photoelectric conversion element 81 generates photocharges on the basis of light incident on the grayscale pixel 80.

The pixel circuit 82 outputs a pixel signal according to the amount of light incident on the basis of the photocharges generated in the photoelectric conversion element 81. The pixel circuit 82 includes a transfer transistor Q21, a reset transistor Q22, an amplification transistor Q23, and a selection transistor Q24. The transfer transistor Q21, the reset transistor Q22, and the amplification transistor Q23 are connected to a floating diffusion (floating diffusion region/impurity diffusion region) FD.

In the present specification, an example will be described in which four transistors in the pixel circuit 82, namely the transfer transistor Q21, the reset transistor Q22, the amplification transistor Q23, and the selection transistor Q24, are, for example, NMOS transistors. The four transistors taken as an example, however, may have any conductivity type. Any of the four transistors may be, for example, a PMOS transistor.

FIG. 16 illustrates an example of a 4Tr configuration in which the pixel circuit 82 includes four transistors (Tr). The number of transistors included in the pixel circuit 82 is not limited to four. For example, a 3Tr configuration may be employed in which the selection transistor Q24 is omitted and the amplification transistor Q23 has a function of the selection transistor Q24, or a configuration of 5Tr or more may be employed in which the number of transistors is increased as necessary, instead.

In the photoelectric conversion element 81, a cathode or an anode (e.g., the cathode) is connected to the transfer transistor Q21, and another (e.g., the anode) is connected to a reference voltage node VRLD such as ground.

The transfer transistor Q21 is used to switch transfer of photocharges. A source and a drain of the transfer transistor Q21 are connected to the photoelectric conversion element 81 and the floating diffusion FD, respectively. The transfer transistor Q21 is turned on by applying a transfer signal TRG at a high level (e.g., at a level of a high-potential side power supply VDD described later) to a gate thereof. As a result, the photocharges accumulated in the photoelectric conversion element 81 are transferred to the floating diffusion FD.

The reset transistor Q22 is used to reset the amount of photocharges in the grayscale pixel 80. A source and a drain of the reset transistor Q22 are connected to the floating diffusion FD and a node of the high-potential side power supply VDD, respectively. The reset transistor Q22 is turned on by applying a reset signal RST at a high level to a gate thereof. As a result, the charges in the floating diffusion FD are discharged to the node of the high-potential side power supply VDD to reset the floating diffusion FD.

The floating diffusion FD accumulates the photocharges transferred from the photoelectric conversion element 81. As a result, the floating diffusion FD has a potential according to the accumulated charges.

A gate of the amplification transistor Q23 has the same potential as the floating diffusion FD, and is used as an input unit of a source follower circuit. A drain and a source of the amplification transistor Q23 are connected to the node of the high-potential side power supply VDD and the selection transistor Q24, respectively. A source voltage of the amplification transistor Q23 changes depending on the potential of the floating diffusion FD.

The selection transistor Q24 is used to perform scan control of the grayscale pixel 80. A selection control signal SEL is applied to a gate of the selection transistor Q24. The selection transistor Q24 is turned on when the selection control signal SEL is at a high level, and a pixel signal Vimg of a voltage level according to the potential of the floating diffusion FD is transmitted from a source of the selection transistor Q24 to a signal line VSL.

For example, in a case where the illuminance of light incident on the photoelectric conversion element 81 is large, a voltage on a cathode side of the photoelectric conversion element 81 decreases. As a result, when the potential of the floating diffusion FD decreases and the selection transistor Q24 is turned on, the low-level pixel signal Vimg output to the signal line VSL. The pixel signal Vimg output from the pixel circuit 82 is input to the analog-to-digital conversion unit 83 (not illustrated) via the signal line VSL.

In a case where the photodetection device 2a in FIG. 15 has the multilayer structure of FIG. 6A, the photoelectric conversion element 81 and a part or all of the pixel circuit 82 are arranged on, for example, the pixel chip 51. Furthermore, in a case where the sensor 20 has the multilayer structure of FIG. 6B, for example, the photoelectric conversion element 81 and the transfer transistor Q21 are arranged on the first chip 53. The reset transistor Q22, the amplification transistor Q23, and the selection transistor Q24, for example, are arranged on the second chip 54. In addition, in a case where the sensor 20 has the multilayer structure of FIG. 6C, the photoelectric conversion element 81 and a part or all of the pixel circuit 82 are arranged on the first pixel chip 56.

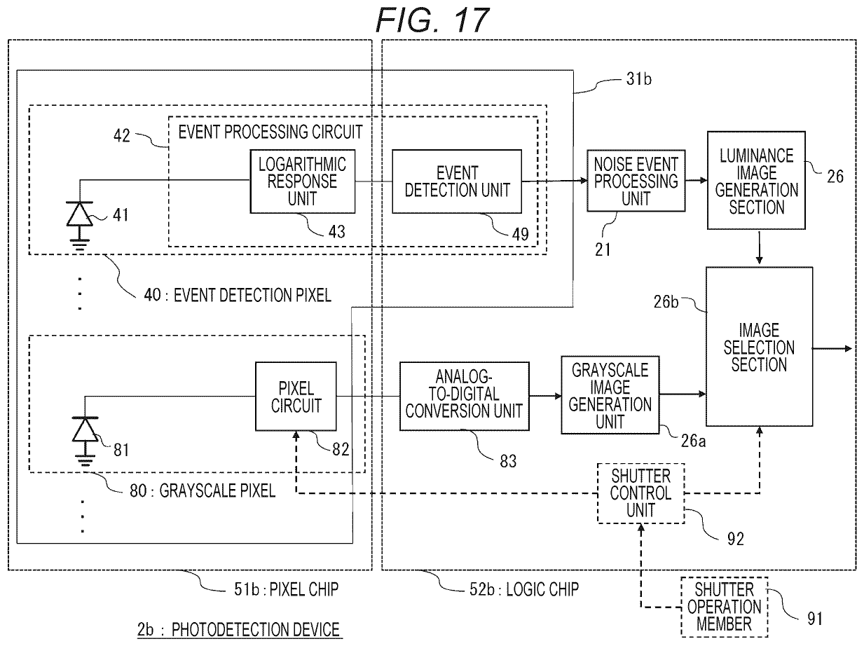

FIG. 17 is a block diagram illustrating a first example of a photodetection device 2 according to a second embodiment of the present disclosure. The photodetection device 2b illustrated in FIG. 17 includes a pixel array unit 31b having a hybrid configuration including a plurality of event detection pixels 40 and a plurality of grayscale pixels 80. In addition, the photodetection device 2b includes a noise event processing unit 21 similar to that in FIG. 2, a luminance image generation section 26 similar to that in FIG. 2, a grayscale image generation unit 26a similar to that in FIG. 15, and an image selection unit 26b. The grayscale pixels 80 are arranged on a pixel chip 51b. A shutter control unit 92 is arranged on a logic chip 52b.

An analog-to-digital conversion unit 83 in FIG. 17 converts pixel signals Vimg output from the grayscale pixels 80 into digital signals. The grayscale image generation unit 26a generates grayscale image data on the basis of the digital signals. The noise event processing unit 21 counts the number of noise events that have occurred in each event detection pixel 40 and generates luminance information. The luminance image generation section 26 generates luminance image data on the basis of the luminance information regarding each event detection pixel 40. The image selection unit 26b exclusively selects and outputs the luminance image data generated by the luminance image generation section 26 or the grayscale image data generated by the grayscale image generation unit 26a. Specifically, the image selection unit 26b outputs the luminance image data until an imaging timing of the grayscale pixels 80, and outputs the grayscale image data at the imaging timing of the grayscale pixels 80.

The photodetection device 2b may include a shutter operation member 91 and a shutter control unit 92. The shutter operation member 91 specifies the imaging timing of the grayscale pixels 80. The shutter control unit 92 generates a control signal in accordance with the operation of the shutter operation member 91. The image selection unit 26b exclusively selects and outputs the luminance image data or the grayscale image data on the basis of a control signal from the shutter control unit 92.

The luminance image data can be generated with lower power consumption than the grayscale image data. The grayscale image data can express gradation with higher definition than the luminance image data. Furthermore, the grayscale image data can include not only monochrome information but also color information. The photodetection device 2b according to the second embodiment can be applied to a surveillance camera or the like.

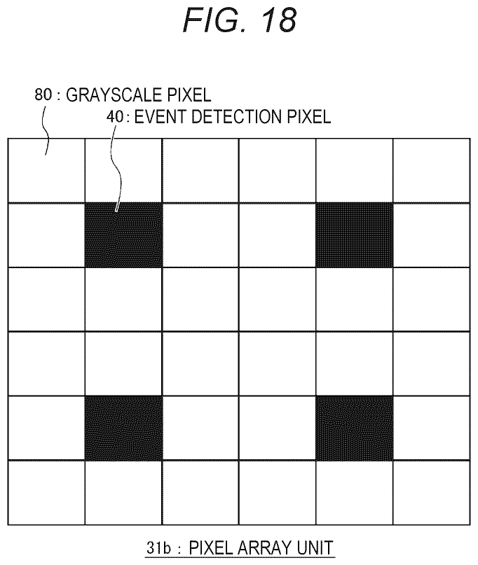

FIG. 18 is a diagram illustrating a first example of a pixel array unit according to the second embodiment of the present disclosure. A pixel array unit 31b illustrated in FIG. 18 includes a plurality of event detection pixels 40 and a plurality of grayscale pixels 80 arranged in such a way as to surround the event detection pixels 40.

The photodetection device 2 according to the second embodiment of the present disclosure may be configured to arbitrarily switch one pixel to the event detection pixel 40 or the grayscale pixel 80.

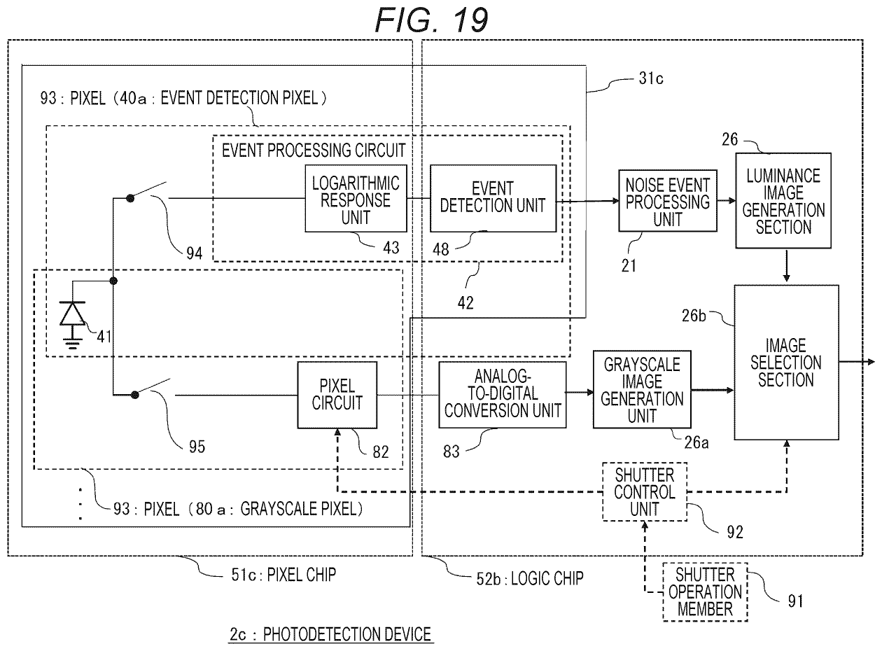

FIG. 19 is a block diagram illustrating a second example of the photodetection device 2 according to the second embodiment of the present disclosure. The photodetection device 2c illustrated in FIG. 19 includes a plurality of pixels 93 in a pixel array unit 31c. The pixels 93 each include a photoelectric conversion element 41, an event processing circuit 42, a pixel circuit 82, an analog-to-digital conversion unit 83, an event readout switch 94, and a grayscale readout switch 95. The event readout switch 94 and the grayscale readout switch 95 are arranged on a pixel chip 51c.

The event readout switch 94 switches whether or not to detect an event. When the event readout switch 94 is on, charges accumulated in the photoelectric conversion element 41 are supplied to the event processing circuit 42. In this case, the pixels 93 are used as event detection pixels 40a.

The grayscale readout switch 95 switches whether to read out grayscale. When the grayscale readout switch 95 is on, the charges accumulated in the photoelectric conversion element 41 are supplied to the pixel circuit 82. In this case, the pixels 93 are used as grayscale pixels 80a.

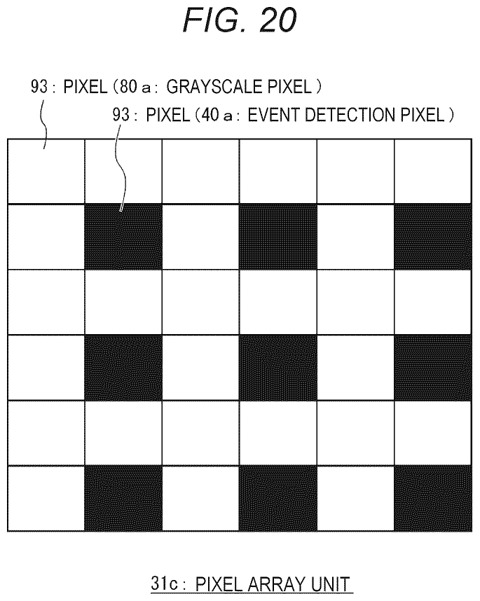

FIG. 20 is a diagram illustrating the pixel array unit according to the second embodiment of the present disclosure. The pixel array unit 31c illustrated in FIG. 20 includes the plurality of pixels 93. Whether to use each of the plurality of pixels 93 as the event detection pixel 40a or the grayscale pixel 80a can be switched.

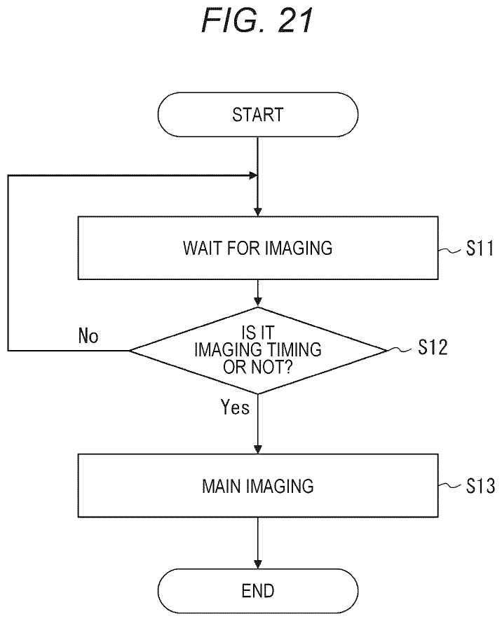

FIG. 21 is a flowchart illustrating imaging processing by a camera including the photodetection device 2c (or the photodetection device 2b) according to the second embodiment of the present disclosure. First, imaging is waited for (step S11). In step S11, the noise event processing unit 21 counts the number of noise events that have occurred in each event detection pixel 40 and generates luminance information for the event detection pixel 40. The luminance image generation section 26 generates luminance image data on the basis of the luminance information regarding each event detection pixel 40.

Subsequently, it is determined whether or not it is an imaging timing of the grayscale pixels 80 (step S12). If it is not the imaging timing of the grayscale pixels 80, the imaging is continuously waited for in step S11. Note that whether or not it is the imaging timing of the grayscale pixels 80 may be determined on the basis of whether or not the shutter operation member 91 is being operated by an imaging operator. If it is the imaging timing of the grayscale pixels 80, next, main imaging processing is performed (step S13). In step S13, the grayscale image data is selected by the image selection unit 26b and displayed on a finder or the like. As a result, the photodetection device 2c can output a captured high-definition grayscale image.

As described above, the photodetection device 2c (or the photodetection device 2b) according to the second embodiment of the present disclosure can generate the luminance image data based on the noise events and the grayscale image data based on the pixel signals Vimg while switching between the two. As a result, it is possible to reduce power consumption by displaying luminance image data until the predetermined imaging timing and to display high-quality grayscale image data at the imaging timing, and it is possible to reduce power consumption and improve image quality.

### Application Example

The technology in the present disclosure can be applied to various products. For example, the technology according to the present disclosure may also be implemented as a device mounted on any type of mobile body such as an automobile, an electric automobile, a hybrid electric automobile, a motorcycle, a bicycle, a personal mobility, an airplane, a drone, a ship, a robot, a construction machine, or an agricultural machine (tractor).

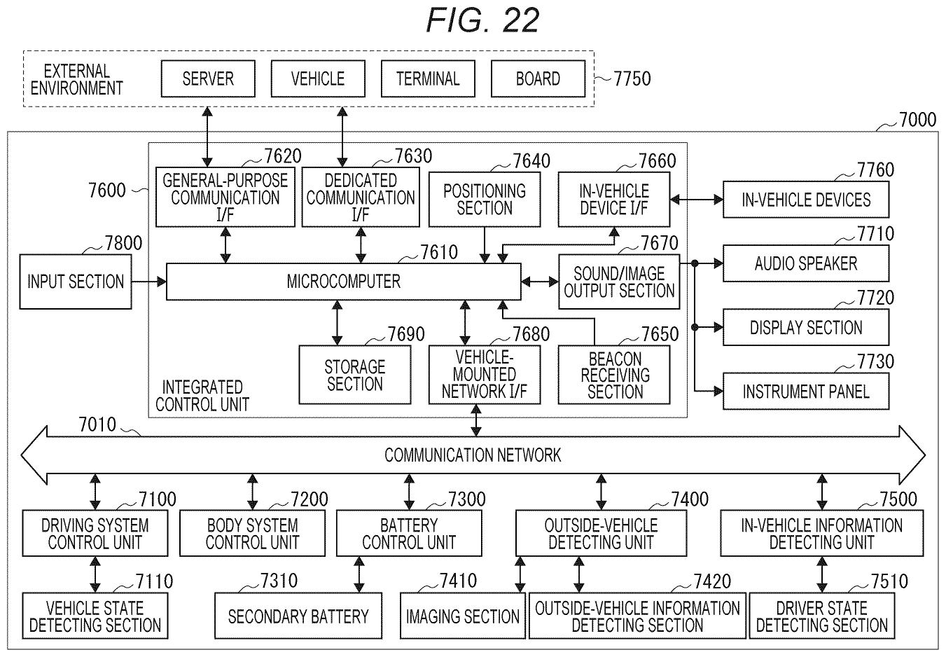

FIG. 22 is a block diagram illustrating an example of schematic configuration of a vehicle control system 7000 as an example of a mobile body control system to which the technology in the present disclosure can be applied. The vehicle control system 7000 includes a plurality of electronic control units connected to each other via a communication network 7010. In the example illustrated in FIG. 22, the vehicle control system 7000 includes a driving system control unit 7100, a body system control unit 7200, a battery control unit 7300, an outside-vehicle information detecting unit 7400, an in-vehicle information detecting unit 7500, and an integrated control unit 7600. The communication network 7010 connecting the plurality of control units to each other may, for example, be a vehicle-mounted communication network compliant with an arbitrary standard such as controller area network (CAN), local interconnect network (LIN), local area network (LAN), FlexRay (registered trademark), or the like.

Each of the control units includes: a microcomputer that performs arithmetic processing according to various kinds of programs; a storage section that stores the programs executed by the microcomputer, parameters used for various kinds of operations, or the like; and a driving circuit that drives various kinds of control target devices. Each of the control units further includes: a network interface (I/F) for performing communication with other control units via the communication network 7010; and a communication I/F for performing communication with a device, a sensor, or the like within and without the vehicle by wire communication or radio communication. A functional configuration of the integrated control unit 7600 illustrated in FIG. 22 includes a microcomputer 7610, a general-purpose communication I/F 7620, a dedicated communication I/F 7630, a positioning section 7640, a beacon receiving section 7650, an in-vehicle device I/F 7660, a sound/image output section 7670, a vehicle-mounted network I/F 7680, and a storage section 7690. The other control units similarly include a microcomputer, a communication I/F, a storage section, and the like.

The driving system control unit 7100 controls the operation of devices related to the driving system of the vehicle in accordance with various kinds of programs. For example, the driving system control unit 7100 functions as a control device for a driving force generating device for generating the driving force of the vehicle, such as an internal combustion engine, a driving motor, or the like, a driving force transmitting mechanism for transmitting the driving force to wheels, a steering mechanism for adjusting the steering angle of the vehicle, a braking device for generating the braking force of the vehicle, and the like. The driving system control unit 7100 may have a function as a control device of an antilock brake system (ABS), electronic stability control (ESC), or the like.

The driving system control unit 7100 is connected with a vehicle state detecting section 7110. The vehicle state detecting section 7110, for example, includes at least one of a gyro sensor that detects the angular velocity of axial rotational movement of a vehicle body, an acceleration sensor that detects the acceleration of the vehicle, and sensors for detecting an amount of operation of an accelerator pedal, an amount of operation of a brake pedal, the steering angle of a steering wheel, an engine speed or the rotational speed of wheels, and the like. The driving system control unit 7100 performs arithmetic processing using a signal input from the vehicle state detecting section 7110, and controls the internal combustion engine, the driving motor, an electric power steering device, the brake device, and the like.

The body system control unit 7200 controls the operation of various kinds of devices provided to the vehicle body in accordance with various kinds of programs. For example, the body system control unit 7200 functions as a control device for a keyless entry system, a smart key system, a power window device, or various kinds of lamps such as a headlamp, a backup lamp, a brake lamp, a turn signal, a fog lamp, or the like. In this case, radio waves transmitted from a mobile device as an alternative to a key or signals of various kinds of switches can be input to the body system control unit 7200. The body system control unit 7200 receives these input radio waves or signals, and controls a door lock device, the power window device, the lamps, or the like of the vehicle.

The battery control unit 7300 controls a secondary battery 7310, which is a power supply source for the driving motor, in accordance with various kinds of programs. For example, the battery control unit 7300 is supplied with information about a battery temperature, a battery output voltage, an amount of charge remaining in the battery, or the like from a battery device including the secondary battery 7310. The battery control unit 7300 performs arithmetic processing using these signals, and performs control for regulating the temperature of the secondary battery 7310 or controls a cooling device provided to the battery device or the like.

The outside-vehicle information detecting unit 7400 detects information about the outside of the vehicle including the vehicle control system 7000. For example, the outside-vehicle information detecting unit 7400 is connected with at least one of an imaging section 7410 and an outside-vehicle information detecting section 7420. The imaging section 7410 includes at least one of a time-of-flight (ToF) camera, a stereo camera, a monocular camera, an infrared camera, and other cameras. The outside-vehicle information detecting section 7420, for example, includes at least one of an environmental sensor for detecting current atmospheric conditions or weather conditions and a peripheral information detecting sensor for detecting another vehicle, an obstacle, a pedestrian, or the like on the periphery of the vehicle including the vehicle control system 7000.

The environmental sensor, for example, may be at least one of a rain drop sensor detecting rain, a fog sensor detecting a fog, a sunshine sensor detecting a degree of sunshine, and a snow sensor detecting a snowfall. The peripheral information detecting sensor may be at least one of an ultrasonic sensor, a radar device, and a LIDAR device (Light detection and Ranging device, or Laser imaging detection and ranging device). Each of the imaging section 7410 and the outside-vehicle information detecting section 7420 may be provided as an independent sensor or device, or may be provided as a device in which a plurality of sensors or devices are integrated.

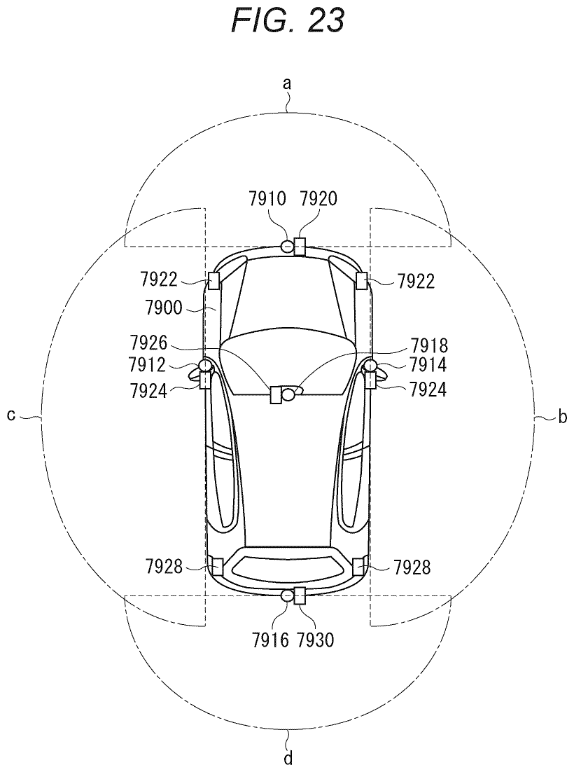

Here, FIG. 23 illustrates an example of installation positions of the imaging section 7410 and the outside-vehicle information detecting section 7420. Imaging sections 7910, 7912, 7914, 7916, and 7918 are, for example, disposed at at least one of positions on a front nose, sideview mirrors, a rear bumper, and a back door of the vehicle 7900 and a position on an upper portion of a windshield within the interior of the vehicle. The imaging section 7910 provided to the front nose and the imaging section 7918 provided to the upper portion of the windshield within the interior of the vehicle obtain mainly an image of the front of the vehicle 7900. The imaging sections 7912 and 7914 provided to the sideview mirrors obtain mainly an image of the sides of the vehicle 7900. The imaging section 7916 provided to the rear bumper or the back door obtains mainly an image of the rear of the vehicle 7900. The imaging section 7918 provided to the upper portion of the windshield within the interior of the vehicle is used mainly to detect a preceding vehicle, a pedestrian, an obstacle, a signal, a traffic sign, a lane, or the like.

Note that FIG. 23 illustrates an example of imaging ranges of the imaging sections 7910, 7912, 7914, and 7916. An imaging range a represents the imaging range of the imaging section 7910 provided to the front nose. Imaging ranges b and c respectively represent the imaging ranges of the imaging sections 7912 and 7914 provided to the sideview mirrors. An imaging range d represents the imaging range of the imaging section 7916 provided to the rear bumper or the back door. A bird's-eye image of the vehicle 7900 as viewed from above can be obtained by superimposing image data imaged by the imaging sections 7910, 7912, 7914, and 7916, for example.

Outside-vehicle information detecting sections 7920, 7922, 7924, 7926, 7928, and 7930 provided to the front, rear, sides, and corners of the vehicle 7900 and the upper portion of the windshield within the interior of the vehicle may be, for example, an ultrasonic sensor or a radar device. The outside-vehicle information detecting sections 7920, 7926, and 7930 provided to the front nose of the vehicle 7900, the rear bumper, the back door of the vehicle 7900, and the upper portion of the windshield within the interior of the vehicle may be a LIDAR device, for example. These outside-vehicle information detecting sections 7920 to 7930 are used mainly to detect a preceding vehicle, a pedestrian, an obstacle, or the like.

Returning to FIG. 22, the description will be continued. The outside-vehicle information detecting unit 7400 makes the imaging section 7410 image an image of the outside of the vehicle, and receives imaged image data. In addition, the outside-vehicle information detecting unit 7400 receives detection information from the outside-vehicle information detecting section 7420 connected to the outside-vehicle information detecting unit 7400. In a case where the outside-vehicle information detecting section 7420 is an ultrasonic sensor, a radar device, or a LIDAR device, the outside-vehicle information detecting unit 7400 transmits an ultrasonic wave, an electromagnetic wave, or the like, and receives information of a received reflected wave. On the basis of the received information, the outside-vehicle information detecting unit 7400 may perform processing of detecting an object such as a human, a vehicle, an obstacle, a sign, a character on a road surface, or the like, or processing of detecting a distance thereto. The outside-vehicle information detecting unit 7400 may perform environment recognition processing of recognizing a rainfall, a fog, road surface conditions, or the like on the basis of the received information. The outside-vehicle information detecting unit 7400 may calculate a distance to an object outside the vehicle on the basis of the received information.

In addition, on the basis of the received image data, the outside-vehicle information detecting unit 7400 may perform image recognition processing of recognizing a human, a vehicle, an obstacle, a sign, a character on a road surface, or the like, or processing of detecting a distance thereto. The outside-vehicle information detecting unit 7400 may subject the received image data to processing such as distortion correction, alignment, or the like, and combine the image data imaged by a plurality of different imaging sections 7410 to generate a bird's-eye image or a panoramic image. The outside-vehicle information detecting unit 7400 may perform viewpoint conversion processing using the image data imaged by the imaging section 7410 including the different imaging parts.

The in-vehicle information detecting unit 7500 detects information about the inside of the vehicle. The in-vehicle information detecting unit 7500 is, for example, connected with a driver state detecting section 7510 that detects the state of a driver. The driver state detecting section 7510 may include a camera that images the driver, a biosensor that detects biological information of the driver, a microphone that collects sound within the interior of the vehicle, or the like. The biosensor is, for example, disposed in a seat surface, the steering wheel, or the like, and detects biological information of an occupant sitting in a seat or the driver holding the steering wheel. On the basis of detection information input from the driver state detecting section 7510, the in-vehicle information detecting unit 7500 may calculate a degree of fatigue of the driver or a degree of concentration of the driver, or may determine whether the driver is dozing. The in-vehicle information detecting unit 7500 may subject an audio signal obtained by the collection of the sound to processing such as noise canceling processing or the like.

The integrated control unit 7600 controls general operation within the vehicle control system 7000 in accordance with various kinds of programs. The integrated control unit 7600 is connected with an input section 7800. The input section 7800 is implemented by a device capable of input operation by an occupant, such, for example, as a touch panel, a button, a microphone, a switch, a lever, or the like. The integrated control unit 7600 may be supplied with data obtained by voice recognition of voice input through the microphone. The input section 7800 may, for example, be a remote control device using infrared rays or other radio waves, or an external connecting device such as a mobile telephone, a personal digital assistant (PDA), or the like that supports operation of the vehicle control system 7000. The input section 7800 may be, for example, a camera. In that case, an occupant can input information by gesture. Alternatively, data may be input which is obtained by detecting the movement of a wearable device that an occupant wears. Further, the input section 7800 may, for example, include an input control circuit or the like that generates an input signal on the basis of information input by an occupant or the like using the above-described input section 7800, and which outputs the generated input signal to the integrated control unit 7600. An occupant or the like inputs various kinds of data or gives an instruction for processing operation to the vehicle control system 7000 by operating the input section 7800.

The storage section 7690 may include a read only memory (ROM) that stores various kinds of programs executed by the microcomputer and a random access memory (RAM) that stores various kinds of parameters, operation results, sensor values, or the like. In addition, the storage section 7690 may be implemented by a magnetic storage device such as a hard disc drive (HDD) or the like, a semiconductor storage device, an optical storage device, a magneto-optical storage device, or the like.

The general-purpose communication I/F 7620 is a communication I/F used widely, which communication I/F mediates communication with various apparatuses present in an external environment 7750. The general-purpose communication I/F 7620 may implement a cellular communication protocol such as global system for mobile communications (GSM (registered trademark)), worldwide interoperability for microwave access (WiMAX (registered trademark)), long term evolution (LTE (registered trademark)), LTE-advanced (LTE-A), or the like, or another wireless communication protocol such as wireless LAN (referred to also as wireless fidelity (Wi-Fi (registered trademark)), Bluetooth (registered trademark), or the like. The general-purpose communication I/F 7620 may, for example, connect to an apparatus (for example, an application server or a control server) present on an external network (for example, the Internet, a cloud network, or a company-specific network) via a base station or an access point. In addition, the general-purpose communication I/F 7620 may connect to a terminal present in the vicinity of the vehicle (which terminal is, for example, a terminal of the driver, a pedestrian, or a store, or a machine type communication (MTC) terminal) using a peer to peer (P2P) technology, for example.

The dedicated communication I/F 7630 is a communication I/F that supports a communication protocol developed for use in vehicles. The dedicated communication I/F 7630 may implement a standard protocol such, for example, as wireless access in vehicle environment (WAVE), which is a combination of institute of electrical and electronic engineers (IEEE) 802.11p as a lower layer and IEEE 1609 as a higher layer, dedicated short range communications (DSRC), or a cellular communication protocol. The dedicated communication I/F 7630 typically carries out V2X communication as a concept including one or more of communication between a vehicle and a vehicle (Vehicle to Vehicle), communication between a road and a vehicle (Vehicle to Infrastructure), communication between a vehicle and a home (Vehicle to Home), and communication between a pedestrian and a vehicle (Vehicle to Pedestrian).

The positioning section 7640, for example, performs positioning by receiving a global navigation satellite system (GNSS) signal from a GNSS satellite (for example, a GPS signal from a global positioning system (GPS) satellite), and generates positional information including the latitude, longitude, and altitude of the vehicle. Incidentally, the positioning section 7640 may identify a current position by exchanging signals with a wireless access point, or may obtain the positional information from a terminal such as a mobile telephone, a personal handyphone system (PHS), or a smart phone that has a positioning function.

The beacon receiving section 7650, for example, receives a radio wave or an electromagnetic wave transmitted from a radio station installed on a road or the like, and thereby obtains information about the current position, congestion, a closed road, a necessary time, or the like. Incidentally, the function of the beacon receiving section 7650 may be included in the dedicated communication I/F 7630 described above.

The in-vehicle device I/F 7660 is a communication interface that mediates connection between the microcomputer 7610 and various in-vehicle devices 7760 present within the vehicle. The in-vehicle device I/F 7660 may establish wireless connection using a wireless communication protocol such as wireless LAN, Bluetooth (registered trademark), near field communication (NFC), or wireless universal serial bus (WUSB). In addition, the in-vehicle device I/F 7660 may establish wired connection by universal serial bus (USB), high-definition multimedia interface (HDMI (registered trademark)), mobile high-definition link (MHL), or the like via a connection terminal (and a cable if necessary) not depicted in the figures. The in-vehicle devices 7760 may, for example, include at least one of a mobile device and a wearable device possessed by an occupant and an information device carried into or attached to the vehicle. The in-vehicle devices 7760 may also include a navigation device that searches for a path to an arbitrary destination. The in-vehicle device I/F 7660 exchanges control signals or data signals with these in-vehicle devices 7760.

The vehicle-mounted network I/F 7680 is an interface that mediates communication between the microcomputer 7610 and the communication network 7010. The vehicle-mounted network I/F 7680 transmits and receives signals or the like in conformity with a predetermined protocol supported by the communication network 7010.

The microcomputer 7610 of the integrated control unit 7600 controls the vehicle control system 7000 in accordance with various kinds of programs on the basis of information obtained via at least one of the general-purpose communication I/F 7620, the dedicated communication I/F 7630, the positioning section 7640, the beacon receiving section 7650, the in-vehicle device I/F 7660, and the vehicle-mounted network I/F 7680. For example, the microcomputer 7610 may calculate a control target value for the driving force generating device, the steering mechanism, or the braking device on the basis of the obtained information about the inside and outside of the vehicle, and output a control command to the driving system control unit 7100. For example, the microcomputer 7610 may perform cooperative control intended to implement functions of an advanced driver assistance system (ADAS) which functions include collision avoidance or shock mitigation for the vehicle, following driving based on a following distance, vehicle speed maintaining driving, a warning of collision of the vehicle, a warning of deviation of the vehicle from a lane, or the like. In addition, the microcomputer 7610 may perform cooperative control intended for automated driving, which makes the vehicle to travel automatedly without depending on the operation of the driver, or the like, by controlling the driving force generating device, the steering mechanism, the braking device, or the like on the basis of the obtained information about the surroundings of the vehicle.

The microcomputer 7610 may generate three-dimensional distance information between the vehicle and an object such as a surrounding structure, a person, or the like, and generate local map information including information about the surroundings of the current position of the vehicle, on the basis of information obtained via at least one of the general-purpose communication I/F 7620, the dedicated communication I/F 7630, the positioning section 7640, the beacon receiving section 7650, the in-vehicle device I/F 7660, and the vehicle-mounted network I/F 7680. In addition, the microcomputer 7610 may predict danger such as collision of the vehicle, approaching of a pedestrian or the like, an entry to a closed road, or the like on the basis of the obtained information, and generate a warning signal. The warning signal may, for example, be a signal for producing a warning sound or lighting a warning lamp.

The sound/image output section 7670 transmits an output signal of at least one of a sound and an image to an output device capable of visually or auditorily notifying information to an occupant of the vehicle or the outside of the vehicle. In the example in FIG. 22, an audio speaker 7710, a display section 7720, and an instrument panel 7730 are illustrated as the output device. The display section 7720 may, for example, include at least one of an on-board display and a head-up display. The display section 7720 may have an augmented reality (AR) display function. The output device may be other than these devices, and may be another device such as headphones, a wearable device such as an eyeglass type display worn by an occupant or the like, a projector, a lamp, or the like. In a case where the output device is a display device, the display device visually displays results obtained by various kinds of processing performed by the microcomputer 7610 or information received from another control unit in various forms such as text, an image, a table, a graph, or the like. In addition, in a case where the output device is an audio output device, the audio output device converts an audio signal constituted of reproduced audio data or sound data or the like into an analog signal, and auditorily outputs the analog signal.

Note that at least two control units connected to each other via the communication network 7010 in the example illustrated in FIG. 22 may be integrated into one control unit. Alternatively, each individual control unit may include a plurality of control units. Further, the vehicle control system 7000 may include another control unit not depicted in the figures. In addition, part or the whole of the functions performed by one of the control units in the above description may be assigned to another control unit. That is, predetermined arithmetic processing may be performed by any of the control units as long as information is transmitted and received via the communication network 7010. Similarly, a sensor or a device connected to one of the control units may be connected to another control unit, and a plurality of control units may mutually transmit and receive detection information via the communication network 7010.

Note that a computer program for achieving each function of the noise event processing unit 21 and the image generation unit 22 according to the present embodiment described with reference to FIG. 2 can be mounted on any control unit or the like. Furthermore, a computer-readable storage medium in which such a computer program is stored can be provided. The storage medium is, for example, a magnetic disk, an optical disc, a magneto-optical disk, a flash memory, or the like. Alternatively, the computer program described above may be distributed via, for example, a network without using a storage medium.

Note that the present technology may have the following configurations.
(1) A photodetection device including:
   a plurality of pixels that detects events based on an amount of change in illuminance of incident light and that detects noise events whose rate of occurrence changes in accordance with the illuminance of the incident light; and
   a luminance information generation unit that generates luminance information for each of the plurality of pixels on the basis of a number of noise events that have occurred in the pixel.
(2) The photodetection device according to (1), in which
   each of the plurality of pixels has at least one illuminance range in which the rate of occurrence of noise events monotonously increases or decreases in accordance with the illuminance, and
   the luminance information generation unit generates the luminance information in the illuminance range.
(3) The photodetection device according to (1) or (2), in which
   the luminance information generation unit generates the luminance information under a situation where the illuminance of the incident light incident on the plurality of pixels does not change.
(4) the Photodetection Device According to Any One of (1) to (3), further including:
   an accumulation unit that accumulates information regarding the noise events for each of the plurality of pixels, in which
   the luminance information generation unit generates the luminance information on the basis of the information regarding the noise events accumulated in the accumulation unit for each of the plurality of pixels.
(5) The photodetection device according to (4), in which the luminance information generation unit generates the luminance information in a case where the information regarding the noise events accumulated in the accumulation unit satisfies a predetermined accumulation condition.
(6) The photodetection device according to (5), in which
   the accumulation unit counts a number of noise events that have occurred in each of the plurality of pixels,
   the accumulation unit accumulates the information regarding the noise events until a total value of the number of noise events that have occurred and been counted for each of the plurality of pixels reaches a predetermined value, and
   in a case where the total value reaches the predetermined value, the luminance information generation unit determines that the accumulation condition is satisfied and generates the luminance information.
(7) The photodetection device according to (5), in which
   the accumulation unit accumulates the information regarding the noise events until either a maximum value of the number of noise events that have occurred in each of the plurality of pixels or an average value of the number of noise events that have occurred in each of the plurality of pixels reaches a predetermined value, and
   in a case where the maximum value or the average value reaches the predetermined value, the luminance information generation unit determines that the accumulation condition is satisfied and generates the luminance information.
(8) The photodetection device according to (5), further including:
   a photodetection element that includes the plurality of pixels and that outputs first event frames including information regarding a plurality of the noise events detected asynchronously by the plurality of pixels, in which
   the accumulation unit accumulates information regarding the noise events included in the first event frames until a total number of first event frames reaches a predetermined value, and
   in a case where the total number reaches the predetermined value, the luminance information generation unit determines that the accumulation condition is satisfied and generates the luminance information.
(9) The photodetection device according to (5), in which
   each of the plurality of pixels asynchronously detects the noise events,
   the accumulation unit counts the number of noise events that have occurred until a predetermined time has elapsed, and
   in a case where the predetermined time has elapsed, the luminance information generation unit determines that the accumulation condition is satisfied and generates the luminance information.
(10) the Photodetection Device According to (5), Further including:
   an event frame generation section that generates second event frames including the information regarding the noise events detected by the plurality of pixels, in which
   the accumulation unit counts the number of noise events that have occurred until a total number of second event frames reaches a predetermined value, and
   in a case where the total number reaches the predetermined value, the luminance information generation unit determines that the accumulation condition is satisfied and generates the luminance information.
(11) The photodetection device according to any one of (1) to (10), further including:
   a luminance image generation unit that generates luminance image data on the basis of the luminance information regarding each of the plurality of pixels, in which
   the luminance image data has a luminance value according to the illuminance for each of the plurality of pixels.
(12) The photodetection device according to (11), in which
   the luminance image generation unit limits, among luminance values of the pixels included in the luminance image data, a luminance value exceeding a predetermined threshold to a predetermined luminance value.
(13) The photodetection device according to (11) or (12), in which
   the luminance image generation unit limits, among luminance values of the pixels included in the luminance image data, a luminance value below a predetermined threshold to a predetermined luminance value.
(14) The photodetection device according to any one of (11) to (13), further including:
   a plurality of first pixels that detects events based on an amount of change in illuminance of incident light and noise events whose rate of occurrence changes in accordance with the illuminance;
   a plurality of second pixels that outputs pixel signals based on the illuminance of the incident light; and
   a grayscale image generation unit that generates grayscale image data on the basis of the pixel signals output from the plurality of second pixels, in which
   the luminance information generation unit generates the luminance information for each of the plurality of first pixels, and the luminance image data has a luminance value according to the luminance for each of the plurality of first pixels.
(15) The photodetection device according to (14), further including:
   an analog-to-digital conversion unit that converts the pixel signals into digital signals, in which
   the grayscale image generation unit generates the grayscale image data on the basis of the digital signal corresponding to each of the plurality of pixels.
(16) The photodetection device according to (14) or (15), in which
   the luminance image data has a resolution lower than a resolution of the grayscale image data, and
   the luminance image data includes monochrome information, whereas the grayscale image data includes at least one of monochrome information or color information.
(17) The photodetection device according to (16), further including:
   an image selection unit that exclusively outputs the luminance image data or the grayscale image data.
(18) The photodetection device according to (17), in which
   the image selection unit selects the luminance image data until an imaging timing of the plurality of second pixels, and selects the grayscale image data at the imaging timing.
(19) An electronic apparatus including:
   a photodetection device that generates luminance information; and
   an information processing unit that performs predetermined information processing on the basis of the luminance information, in which
   the photodetection device includes:
      a plurality of pixels that detects events based on an amount of change in illuminance of incident light and that detects noise events whose rate of occurrence changes in accordance with the illuminance of the incident light; and
      a luminance information generation unit that generates the luminance information for each of the plurality of pixels on the basis of a number of noise events that have occurred in the pixel.

Aspects of the present disclosure are not limited to the above-described individual embodiments, and include various modifications that can be conceived by those skilled in the art, and the effects of the present disclosure are not limited to those described above. That is, various additions, modifications, and partial deletions may be made without departing from the conceptual idea and spirit of the present disclosure derived from the matters defined in the claims and equivalents thereof.

### REFERENCE SIGNS LIST

1, 1a Electronic apparatus
2, 2a, 2b, 2c, 100 Photodetection device
3 Storage unit
4 Control unit
11 Imaging lens
12 Signal line
13 Control line
20, 20a, 20b, 20c, 20d Sensor
20e Sensor main unit
21 Noise event processing unit
22 Image generation unit
23 Noise event accumulation section
24 Luminance information generation section
25 Event frame generation section
26 Luminance image generation section
26a Grayscale image generation unit
26b Image selection unit
27 Event image generation unit
31, 31a, 31b, 31c Pixel array unit
32 Drive circuit
33 X arbiter
34 Y arbiter
35 System control unit
36 Event frame generation section
40, 40a Event detection pixel
41, 81 Photoelectric conversion element
42 Event processing circuit
43 Logarithmic response unit
43a Transfer section
43b Charge-to-voltage conversion section
44 Buffer
45 Differentiator circuit
46 Reset control circuit
47 Comparator
48 Output circuit
49 Event detection unit
51, 51a, 51b, 51c Pixel chip
52, 52a, 52b Logic chip
53 First chip
54 Second chip
55 Third chip
56 First pixel chip
57 Second pixel chip
61 Event frame
61a, 62a, 62b, 62c Event data
63 Accumulated event frame
63a Pixel data
71 Information processing unit
72 Calibration processing section
80, 80a Grayscale pixel
82 Pixel circuit
83 Analog-to-digital conversion unit
91 Shutter operation unit
92 Shutter control unit
93 Pixel
94 Event readout switch
95 Grayscale readout switch

1. A photodetection device comprising:
a plurality of pixels that detects events based on an amount of change in illuminance of incident light and that detects noise events whose rate of occurrence changes in accordance with the illuminance of the incident light; and
a luminance information generation unit that generates luminance information for each of the plurality of pixels on a basis of a number of noise events that have occurred in the pixel.

2. The photodetection device according to claim 1, wherein
each of the plurality of pixels has at least one illuminance range in which the rate of occurrence of noise events monotonously increases or decreases in accordance with the illuminance, and
the luminance information generation unit generates the luminance information in the illuminance range.

3. The photodetection device according to claim 1, wherein
the luminance information generation unit generates the luminance information under a situation where the illuminance of the incident light incident on the plurality of pixels does not change.

4. The photodetection device according to claim 1, further comprising:
an accumulation unit that accumulates information regarding the noise events for each of the plurality of pixels, wherein
the luminance information generation unit generates the luminance information on a basis of the information regarding the noise events accumulated in the accumulation unit for each of the plurality of pixels.

5. The photodetection device according to claim 4, wherein
the luminance information generation unit generates the luminance information in a case where the information regarding the noise events accumulated in the accumulation unit satisfies a predetermined accumulation condition.

6. The photodetection device according to claim 5, wherein
the accumulation unit counts a number of noise events that have occurred in each of the plurality of pixels,
the accumulation unit accumulates the information regarding the noise events until a total value of the number of noise events that have occurred and been counted for each of the plurality of pixels reaches a predetermined value, and
in a case where the total value reaches the predetermined value, the luminance information generation unit determines that the accumulation condition is satisfied and generates the luminance information.

7. The photodetection device according to claim 5, wherein
the accumulation unit accumulates the information regarding the noise events until either a maximum value of the number of noise events that have occurred in each of the plurality of pixels or an average value of the number of noise events that have occurred in each of the plurality of pixels reaches a predetermined value, and
in a case where the maximum value or the average value reaches the predetermined value, the luminance information generation unit determines that the accumulation condition is satisfied and generates the luminance information.

8. The photodetection device according to claim 5, further comprising:
a photodetection element that includes the plurality of pixels and that outputs first event frames including information regarding a plurality of the noise events detected asynchronously by the plurality of pixels, wherein
the accumulation unit accumulates information regarding the noise events included in the first event frames until a total number of first event frames reaches a predetermined value, and
in a case where the total number reaches the predetermined value, the luminance information generation unit determines that the accumulation condition is satisfied and generates the luminance information.

9. The photodetection device according to claim 5, wherein
each of the plurality of pixels asynchronously detects the noise events,
the accumulation unit counts the number of noise events that have occurred until a predetermined time has elapsed, and
in a case where the predetermined time has elapsed, the luminance information generation unit determines that the accumulation condition is satisfied and generates the luminance information.

10. The photodetection device according to claim 5, further comprising:
an event frame generation section that generates second event frames including the information regarding the noise events detected by the plurality of pixels, wherein
the accumulation unit counts the number of noise events that have occurred until a total number of second event frames reaches a predetermined value, and
in a case where the total number reaches the predetermined value, the luminance information generation unit determines that the accumulation condition is satisfied and generates the luminance information.

11. The photodetection device according to claim 1, further comprising:
a luminance image generation unit that generates luminance image data on a basis of the luminance information regarding each of the plurality of pixels, wherein
the luminance image data has a luminance value according to the illuminance for each of the plurality of pixels.

12. The photodetection device according to claim 11, wherein the luminance image generation unit limits, among luminance values of the pixels included in the luminance image data, a luminance value exceeding a predetermined threshold to a predetermined luminance value.

13. The photodetection device according to claim 11, wherein
the luminance image generation unit limits, among luminance values of the pixels included in the luminance image data, a luminance value below a predetermined threshold to a predetermined luminance value.

14. The photodetection device according to claim 11, further comprising:
a plurality of first pixels that detects events based on an amount of change in illuminance of incident light and noise events whose rate of occurrence changes in accordance with the illuminance;
a plurality of second pixels that outputs pixel signals based on the illuminance of the incident light; and
a grayscale image generation unit that generates grayscale image data on a basis of the pixel signals output from the plurality of second pixels, wherein
the luminance information generation unit generates the luminance information for each of the plurality of first pixels, and the luminance image data has a luminance value according to the illuminance for each of the plurality of first pixels.

15. The photodetection device according to claim 14, further comprising:
an analog-to-digital conversion unit that converts the pixel signals into digital signals, wherein
the grayscale image generation unit generates the grayscale image data on a basis of the digital signal corresponding to each of the plurality of pixels.

16. The photodetection device according to claim 14, wherein
the luminance image data has a resolution lower than a resolution of the grayscale image data, and
the luminance image data includes monochrome information, whereas the grayscale image data includes at least one of monochrome information or color information.

17. The photodetection device according to claim 16, further comprising:
an image selection unit that exclusively outputs the luminance image data or the grayscale image data.

18. The photodetection device according to claim 17, wherein
the image selection unit selects the luminance image data until an imaging timing of the plurality of second pixels, and selects the grayscale image data at the imaging timing.

19. An electronic apparatus comprising:
a photodetection device that generates luminance information; and
an information processing unit that performs predetermined information processing on a basis of the luminance information, wherein
the photodetection device includes:
a plurality of pixels that detects events based on an amount of change in illuminance of incident light and that detects noise events whose rate of occurrence changes in accordance with the illuminance of the incident light; and
a luminance information generation unit that generates the luminance information for each of the plurality of pixels on a basis of a number of noise events that have occurred in the pixel.
